(19) United States
(12) Patent Application Publication
(10) Pub. No.: US 2019/0372573 A1
(43) Pub. Date: Dec. 5, 2019

(54) Wires replacing transistors enabling light speed

(71) Applicant: Rashad Zaguia, Ksar Helal (TN)

(72) Inventor: Rashad Zaguia, Ksar Helal (TN)

(21) Appl. No.: 16/024,909

(22) Filed: Jul. 1, 2018

Related U.S. Application Data
(63) Continuation-in-part of application No. 15/992,681, filed on May 30, 2018, now abandoned.

(51) Int. Cl. H03K 19/173; H03K 19/20; G02F 3/00

(52) U.S. Cl. CPC H03K 19/173; G02F 3/00; H03K 19/20

(57) ABSTRACT

A wire is a universal function.

### BACKGROUND OF THE INVENTION

My objective was to create universal logical gates {nor,nand} by other means then transistors.

If I could implement (create one of {Nand,Nor} functions) with verification only (using {not(xor)} function only) like shown in FIG. 2 (used xors) most problems would solve. FIG. 2 is an approximation of a nand (because the inputs have to be allowed to change by the output) and it simplifies to making a {nand, nor} with wires. It is getting verification and implementation closer to solve faster.

### BRIEF SUMMARY OF THE INVENTION

It is about very fast logical gates, building block processes of processors made with any (light or electric) conductor.

It avoids or reduces rare earth resources usage.

Logical gates can be used to implement many thinks like: a processor, an asynchronous state machine or a software.

Fast processors are used for many purposes like simulation and optimization.

(I use optimization for agriculture, construction and economics but it can be used for other thinks).

### BRIEF DESCRIPTION OF THE SEVERAL VIEWS OF THE DRAWING

(See definitions first)

FIG. 0: Some of the older using transistors, implementations of the simple_function {nand}.

FIG. 1: Some of the older using transistors, implementations of the simple_function {nor}.

FIG. 2: Making a special simple_function {nand} using the simple_function {xor} only.

FIG. 3: Showing the double_functions {x,not(x)} with wires only.

FIG. 4: Showing some process steps of how a double_value entering the double_Input {Input0} gives the same double_value to the double_output {Output1} using two times a wire to achieve the double_function {x} for the case: 1 gives 1.

Following the same steps we could show that 0 would give 0.

| | | |
|---|---|---|
| To remark that | 1 | is encoding 0, |
| | 0 | |
| and that | 0 | is encoding 1. |
| | 1 | |

FIG. 5: Showing some process steps of how a double_value entering the double_Input {Input0} gives the other double_value to the double_output {Output0} using two times a wire to achieve the double_function {not(x)} for the case: 1 gives 0.

Following the same steps we could show that 0 would give 1.

FIG. 6 to FIG. 9:

Demonstrating the steps of the processes of all the possible cases of a simple_function {majority_vote} of 3 simple_inputs {Const, Input1, Input2} and an approximation of their result simple_output {out} using wires only.

FIG. 10 to FIG. 33 are an electric version of the light behavior described in FIG. 6 to FIG. 9

Showing a {majority_vote} simple_function of 3 simple_inputs {Input1, Input2, Const} and an approximation of their {Output0} result, using wires (resistances) only.

1 is encoded as power source (+).

0 is encoded as power source (−).

R is a resistance.

If we set the {Const} simple_input to 0, inputs {Input1, Input2} and output {Output0} would approximate a simple_function {“and” }.

If we set the {Const} simple_input to 1, inputs {Input1, Input2} and output {Output0} would approximate a simple_function {“or” }.

FIG. 34 to FIG. 44

Demonstrating the steps of the processes of all the possible cases of a simple_function {“and” }.

A wire gets from {in} through two buttons to {out}.

{in} is put to a value,

{out} would have a Super_value expressing the “and” of the two buttons.

FIG. 45 to FIG. 55

Demonstrating the steps of the processes of all the possible cases of a simple_function {“or” }.

A wire gets from {in} splitting to two wires through two buttons and reuniting to {out}.

{in} is put to a value,

{out} would have a Super_value expressing the “or” of the two buttons.

FIG. 56 to FIG. 63:

Demonstrating the steps of the processes of all the possible cases of a double_function {Nand}.

Showing some possible interactions of 2 different lights, encoding {0, 1} values, that are encoding double_values, on top of a structure of wires making a {Nand} double_function, with the double_inputs {Input_1,Input_2} and the double_output {output0}.

To have a {Nand} {const} is set to 0.

Following the same steps we could show that when {const} is set to 1 the demonstrated double_function becomes a {Nor}.

FIG. 64 to FIG. 87

If:

1 is encoding 0,

0

and

0 is encoding 1.

1

Those figures are demonstrating the steps of the processes of all the possible cases of a double_super_function {Nand}.

If:

1 is encoding 1,

0

and

0 is encoding 0.

1

Those figures are demonstrating the steps of the processes of all the possible cases of a double_super_function {Nor}.

FIG. 88 to FIG. 99:

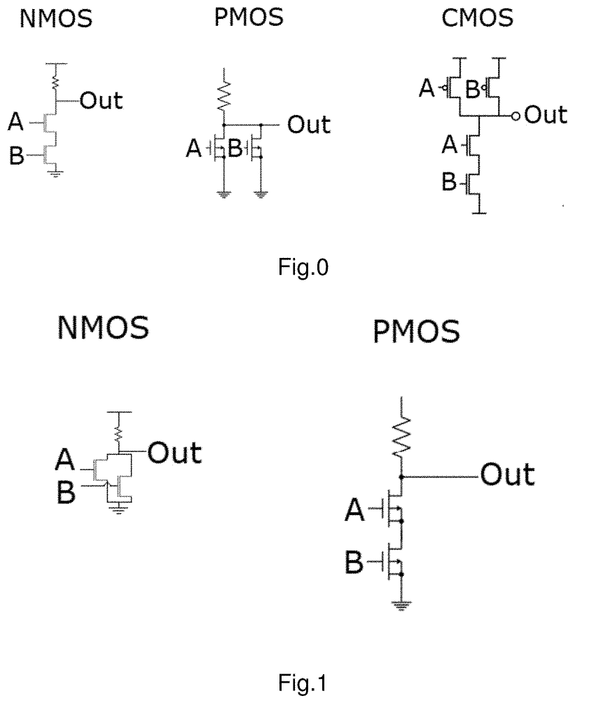

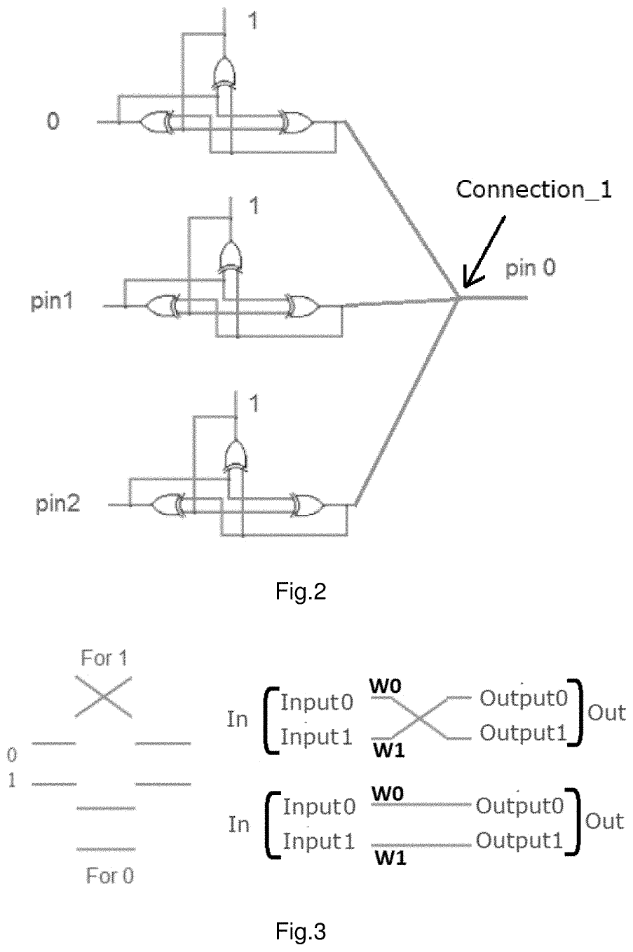

If:

1 is encoding 0,

0

and

0 is encoding 1.

1

Those figures are demonstrating the steps of the processes of all the possible cases of a universal double_function {nor} made with the simple_functions {“and”,“or” } and the double_function {not(x)}.

If:

1 is encoding 1,

0

and

0 is encoding 0.

1

Those figures are demonstrating the steps of the processes of all the possible cases of a universal double_function {nand} made with the simple_functions {“and”,“or” } and the double_function {not(x)}.

### DETAILED DESCRIPTION OF THE INVENTION

### Definitions

Upper case or lower case are the same.

### Example

Wire is the same then wire.
Zero, one or many times of the described by a number or by a word is indicated by adding an “s” to the number or to the word.

Unless redefined,

### Example

Wires is 1 wire.

Wires can also be many times 1 wire.
A code is the relationship between the describer and the described.

A code is put in a form of the exercise of the relationship, with the words: “is encoded as” or “is encoding”.

describer “is encoded as” described.

The reverse sentence telling the same think would be:

described “is encoding” describer. (without “when used).

Codes can be put between { } in a serie where the order matters.

Example: {code2, code1, code0}.

Codes put between { } are codes put in a set.

A code can be a set of codes.

The cardinality of a set is the number of codes put inside without counting the codes {0, 1}. indices of codes in a set start with 0 and add 1 every time counting from right to left without counting the codes {0,1}.
Exchangeable_codes are 2 sets of codes of the same cardinality.
   Two codes or two sets are exchangeable_codes, when codes keeping their indices, can change in the same time the set they belong to without involving new sets, and without changing the nature of what they are encoding.
Fully_exchangeable_codes are 2 sets of codes of the same cardinality.
   Two codes or two sets are fully exchangeable when all codes keeping their indices, can change in the same time the set they belong to, without involving new sets, and without changing the nature of what they are encoding.
A reordrable_code is a set of codes that can change their indices (their order).
Equal_codes are codes where any 2 are exchangeable_codes.
A range_of_encodings are many encodings described by one describer.
A 0 is encoded by a physical characteristic of a light or an electric current.
A 1 is encoded by a physical characteristic of a light or an electric current.
All 0s are in the same range_of_encodings.
All 1s are in the same range_of_encodings.
The encodings of 0s are different from the encodings of is.
   0 range_of_encodings is different from 1 range_of_encodings.
A math serie is a serie of numbers.
   An infinite math serie or an infinite serie is an infinite list of numbers offten defined by a formula.
   Example starting from 0 the n-th element=2 to_the_power_of_n
   Would be the serie: 1, 2, 4, 8, 16 . . .
An approximation is when 0 range_of_encodings is an infinite serie that is different from but gets close to 1 range_of_encodings infinite serie.
   An approximation as defined here respects the diffrence between:
   0 range_of_encodings and 1 range_of_encodings.
   This challenges materials to distinguish the difference between the 2 values after a number of approximations.
Repeating a value is distinguishing an encoding value and regenerating a new encoding, in the range_of_encodings of the value, very far from the range_of_encodings of the other value. This may be also called repeating a signal or repeating an encoding.
A value is one of the set of codes (of digits) {0, 1}.
A wire is a transmitter of a value.
   usages:
      A value can be assigned to a wire.
      A wire can be assigned a value.
      A wire is put to a value.
      Value entering wire
      Gives value to output
A void is an encoding that do not belong to 0 range_of_encodings and do not belong to 1 range_of_encodings. It is an encoding that can be replaced by a 0 encoding when both are co-existing. it can also be replaced by a 1 encoding when both are co-existing. For example ambient light as an encoding can be void.
A wire at void is a wire that is not transmitting a value.
An order_of two distinct values is from big to small or from small to big.
   0 then 1 is an order.
   1 then 0 is an order.
   Those are the only orders of two distinct values.
A simple_value is a value
A double_value is two distinct simple_values.
   A double_value have only 2 distinct orders.
   0 is encoded as an order
   1 is encoded as an order
   The encoding of 0 is different from the encoding of 1.
A double_wire is made with two wires and is a transmitter of a double_value.
A simple_input is a wire.
A double_input is a double_wire
An simple_output is a wire.
A double_output is a double_wire.
An input can be simple_input or can be double_input.
An output can be simple_output or can be double_output.
A simple_function has simple_inputs and simple_outputs.
A double_function has double_inputs and double_outputs.
A function has inputs and outputs.
A function can be one simple_function or can be one double_function.
A function assign output values to all the possible values of all Inputs.

### Example 1

not(xor)=nxor=xnor is defined as:

| All the possible values of all Inputs. | assigned Output values |
|---|---|
| 00 | 1 |
| 01 | 0 |
| 10 | 0 |
| 11 | 1 |

### Example 2

x is defined as:

| All the possible values of all Inputs. | assigned Output values |
|---|---|
| 0 | 0 |
| 1 | 1 |

Notice that a wire can be seen as a simple_function {x}.

### Example 3

not(x) is defined as:

| All the possible values of all Inputs. | assigned Output values |
|---|---|
| 0 | 1 |
| 1 | 0 |

Functions like {xor,not(xor),“or”,“and”,x,not(x),nand, nor} are knowledge of humanity.
A universal function is one function that can make when used alone, one or many times, the structure of any function.
{Nand, Nor} functions are universal, it is knowledge of humanity.
A structure of a function is made with selected functions having some, none or all their values of outputs selected to be values of some, none or all their inputs.
A structure of wires is a structure of a function with wire as the only type of selected functions.
A function that can make the structure of a universal function is universal.
Many different functions that make the structure of a universal function are called here a universal group of functions.
A connection is between outputs and an input having the values of all outputs be the value of the input.

The value of the input is in a range_of_encodings, it is an approximation of 1 or an approximation of 0.

Notice:
Wires are resistances.
It is known that a resistance can't dissipate a voice an electric current or a light passing through it to a total not existent.
The description of values through time as steps on top of the description of a prefixed structure of wires is the description of a process.
As the travel of the values of a function between inputs and outputs, takes some time, a function is a process.
An implementation of a function is often a structure of the function made with other functions.
Out of order processes (steps) are processes that require some to finish before some to start. Example process 1 would start if process 2 and process 3 would finish.
Out of order processes can define parallel processing. (also known as out of order execution).
Other then being a structure of a function made with other functions, an implementation as a process is also described by out of order processes (steps).
A named structure and a named out of order processes (steps) would be in the specifications before referencing them in the claims.
A Super_1 is a value.
A Super_0 is a void.
A Super_value is one of the set of codes (of digits) {Super_0, Super_1}.

Notice: {0,1} could be used instead.
A Super_wire is a transmitter of a super_value. A Super_wire can be often expressed by two wires one leaving the Super_output and one returning to the Super_output, we send a value to the leaving wire and we read a super_value from the returning wire.
A Super_output is a super_wire.
A Super_input is a super_wire.
A super_function has super_inputs and super_outputs.
A Super_button of type Y cuts a super_wire when put to 0 and connects a super_wire when put to 1.
A Super_button of type Z connects a super_wire when put to 0 and cuts a super_wire when put to 1.
An super_order of two distinct super_values is from big to small or from small to big.
   Super_0 then Super_1 is a Super_order.
   Super_1 then Super_0 is a Super_order.
   Those are the only Super_orders of two distinct Super_values.
A double_super_value is two distinct Super_values.
   A double_super_value have only 2 distinct Super_orders.
   Super_0 is encoded as a Super_order.
   Super_1 is encoded as a Super_order.
   The encoding of Super_0 is different from the encoding of Super_1.
A double_super_button is a configuration of two super_buttons representing a double_super_value (by default it is two super_buttons of type y),
A double_super_wire is made with two super_wires that are preferably of two distinct Super_values forming a double_super_value.
A double_super_output is a double_super_wire having a double_super_value.
A double_super_input is a double_super_wire preferably having a double_super_value.
A double_super_function has double_super_inputs and double_super_outputs.
A function can be one double_super_function or one super_function.
An s_input can be a Super_input or a double_super_input
An s_output can be a Super_output or can be a double_simple_output.
Like the function defined above an s_function assign s_output values to all the possible values of all s_Inputs. Instead of using equal_codes we would use super_equal_codes when we manage equivalences between super_values and values. Example: an s_function {nand} and an function {nand} have super_equal_codes. Super_equal_codes include equal_codes.
Proving that any function can be achieved using a prefixed structure of wires is what follows.

Detailed Structures and Processes:

By default:

1 is encoding 0,

0

and

0 is encoding 1.

1

If unspecified flipping the encoding of a value is a possibility that would not change the described.

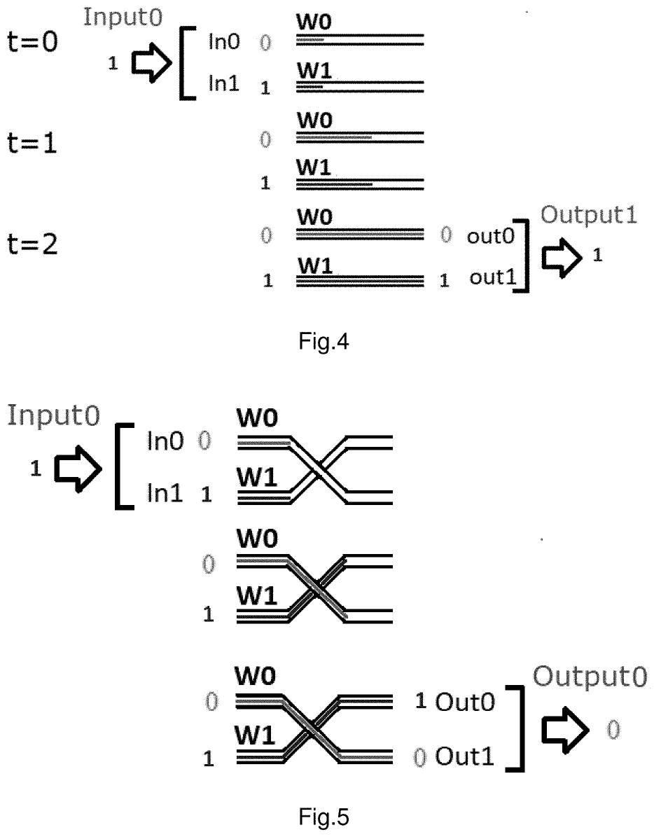

FIG. 4:

Structure_of_double_function_x:

A double_function {x} of double_input {input0} and double_output {output1}.

The double_input {input0} is made with two simple_inputs {In0, Inl}.

The double_output {output1} is made with two simple_outputs {out0, out1}.

{in0} and {out0} are facing each other.

{in1} and {out1} are facing each other.

{in0} and {out0} are the same wire encoded as W0.

{in1} and {out1} are the same wire encoded as W1.

W0 is different from W1 (no connection).

simple_inputs {in0,inl} and simple_outputs {out0, out1} are_fully_exchangeable.

Given this figure a double_function {x} can be encoded as {W0, W1} it can also be encoded as {in0, in1} or as {out0, out1}. the 3 of them are equal_codes.

Processes_of_double_function_x:

A wire is divided to 3 parts to make the description easy.

General Process:

The last third of the two distinct and parallel wires as two processes would start if the middle third as two processes of the two wires ends.

The middle third of the two distinct and parallel wires as two processes would start if the first third as two processes of the two wires ends.
Case: double_value 0 gives double_value 0,

The first third of the two distinct and parallel wires as two processes would start if the double_value 0 is presented at {input0}.

The termination of the last third as two processes of the two wires would have {output1} have the double_value 0.
Case: double_value 1 gives double_value 1,

The first third of the two distinct and parallel wires as two processes would start if the double_value 1 is presented at {input0}.

The termination of the last third as two processes of the two wires would have {output1} have the double_value 1.

FIG. 5

Structure_of_double_function_not_x:

A double_function {not(x)} of double_input {input0} and double_output {output0}.

The double_input {input0} is made with the two of simple_inputs {In0, In1}.

The double_output {output0} is made with the two of simple_outputs {out0, out1}.

{in0} and {out0} are facing each other.

{in1} and {out1} are facing each other.

{in0} and {out1} are the same wire encoded as W0.

{in1} and {out0} are the same wire encoded as W1.

W0 is different from W1 (no connection).

simple_inputs {in0,in1} and simple_outputs {out0, out1} are fully_exchangeable.

Given this figure a double_function {not(x)} can be encoded as {W0, W1} it can also be encoded as {in0, in1} or as {out1, out0}. the 3 of them are equal_codes.

To remark that double_functions include simple_functions for example {in1,out1} would be incoding a simple_function{not(x)}.

Processes_of_double_function_not_x:

A wire is divided to 3 parts to make the description easy.

General Process:

The last third of the two distinct and parallel wires as two processes would start if the middle third as two processes of the two wires ends.

The middle third of the two crossing each other and distinct wires as two processes would start if the first third as two processes of the two wires ends.
Case: double_value 0 gives double_value 1,

The first third of the two distinct and parallel wires as two processes would start if the double_value 0 is presented at {input0}.

The termination of the last third as two processes of the two wires would have {output0} have the double_value 1.
Case: double_value 1 gives double_value 0,

The first third of the two distinct and parallel wires as two processes would start if the double_value 1 is presented at {input0}.

The termination of the last third as two processes of the two wires would have {output0} have the double_value 0.

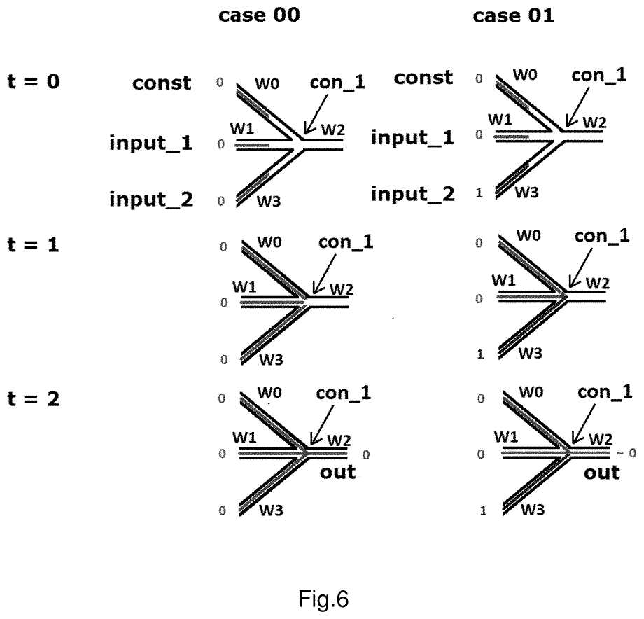

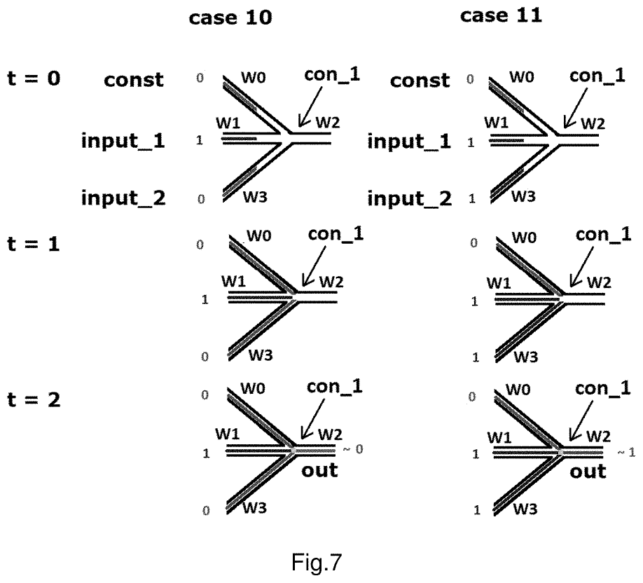

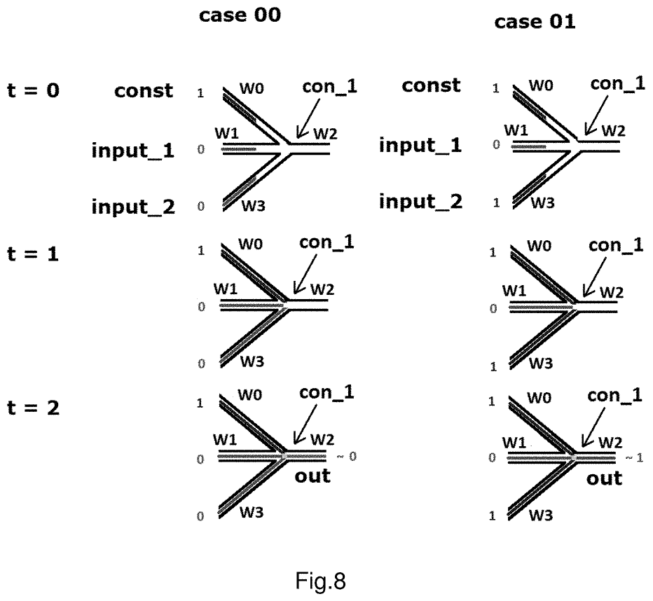

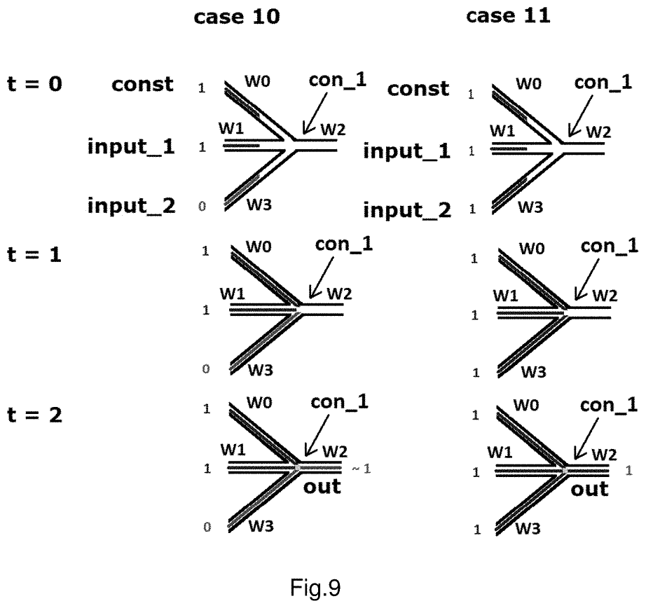

FIG. 6 to FIG. 9

Structure_of_double_function_majority_vote:

A {majority_vote} simple_function of 3 simple_inputs {Const, Input_1, Input_2} and an approximation of their result simple_output {out} using a structure of wires.

It is composed of:
Input {Const} is a wire encoded as W0.
Input {Input_1} is a wire encoded as W1.
Input {Input_2} is a wire encoded as W3.
Output {Out} is a wire encoded as W2.
W0, W1, W2 and W3 are functions having Inputs and outputs.
The outputs of W0, W1 and W3 and the input of W2 are a connection encoded as Con 1.
{const, input1, input2} is a reordrable_code.

Given this figure a simple_function {majority_vote} can be encoded as {W0, W1,W3,W2}. It can also be encoded as {const, input_1, input_2, out}. The two are equal_codes.

Processes_of_double_function_majority_vote:

w0,w1 and w3 are wires divided to 2 parts to make the description easy.

General Process

The wire w2 as a process would start if con_1 would be having the values of the processes of the second halfs of the wires w0,w1 and w3 when they end.

The processes of the second halfs of the wires w0,w1 and w3 would start if the processes of the first halfs of the wires w0,w1 and w3 would end respectively,
Case: {const} is put to simple_value 0 {majority_vote} behaves like an {“and” }.
Case: simple_values 00 give simple_value 0

Processes of the first halfs of the wires w0,w1 and w3 would start if values 0 0 0 are presented to {const, Input_1, Input_2} respectively.

The termination of w2 as a process would have {out} have the simple_value 0. (in the range_of_encodings of 0).
Case: simple_values 01 give simple_value 0

Processes of the first halfs of the wires w0,w1 and w3 would start if values 0 0 1 are presented to {const, Input_1, Input_2} respectively.

The termination of w2 as a process would have {out} have the simple_value 0. (in the range_of_encodings of 0).
Case: simple_values 10 give simple_value 0

Processes of the first halfs of the wires w0,w1 and w3 would start if values 0 1 0 are presented to {const, Input_1, Input_2} respectively.

The termination of w2 as a process would have {out} have the simple_value 0. (in the range_of_encodings of 0).
Case: simple_values 11 give simple_value 1

Processes of the first halfs of the wires w0,w1 and w3 would start if values 0 1 1 are presented to {const, Input_1, Input_2} respectively.

The termination of w2 as a process would have {out} have the simple_value 1. (in the range_of_encodings of 1).
Case: {const} is put to simple_value 1 {majority_vote} behaves like an {“or” }.
Case: simple_values 00 give simple_value 0

Processes of the first halfs of the wires w0,w1 and w3 would start if values 1 0 0 are presented to {const, Input_1, Input_2} respectively.

The termination of w2 as a process would have {out} have the simple_value 0. (in the range_of_encodings of 0).
Case: simple_values 01 give simple_value 1

Processes of the first halfs of the wires w0,w1 and w3 would start if values 1 0 1 are presented to {const, Input_1, Input_2} respectively.

The termination of w2 as a process would have {out} have the simple_value 1. (in the range_of_encodings of 1).
Case: simple_values 10 give simple_value 1

Processes of the first halfs of the wires w0,w1 and w3 would start if values 1 1 0 are presented to {const, Input_1, Input_2} respectively.

The termination of w2 as a process would have {out} have the simple_value 1. (in the range_of_encodings of 1).
Case: simple_values 11 give simple_value 1

Processes of the first halfs of the wires w0,w1 and w3 would start if values 1 1 1 are presented to {const, Input_1, Input_2} respectively.

The termination of w2 as a process would have {out} have the simple_value 1. (in the range_of_encodings of 1).

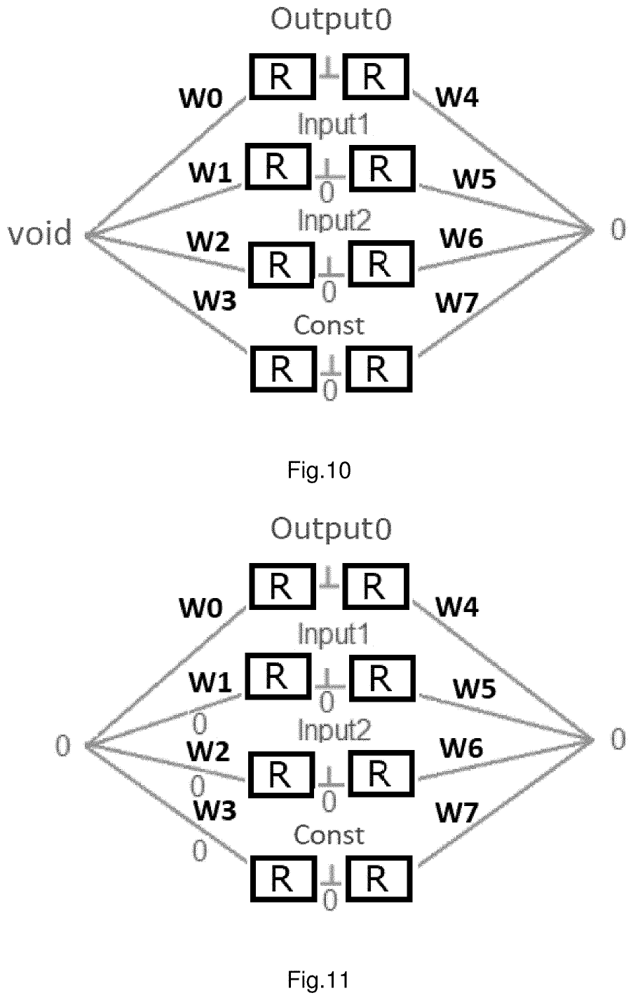

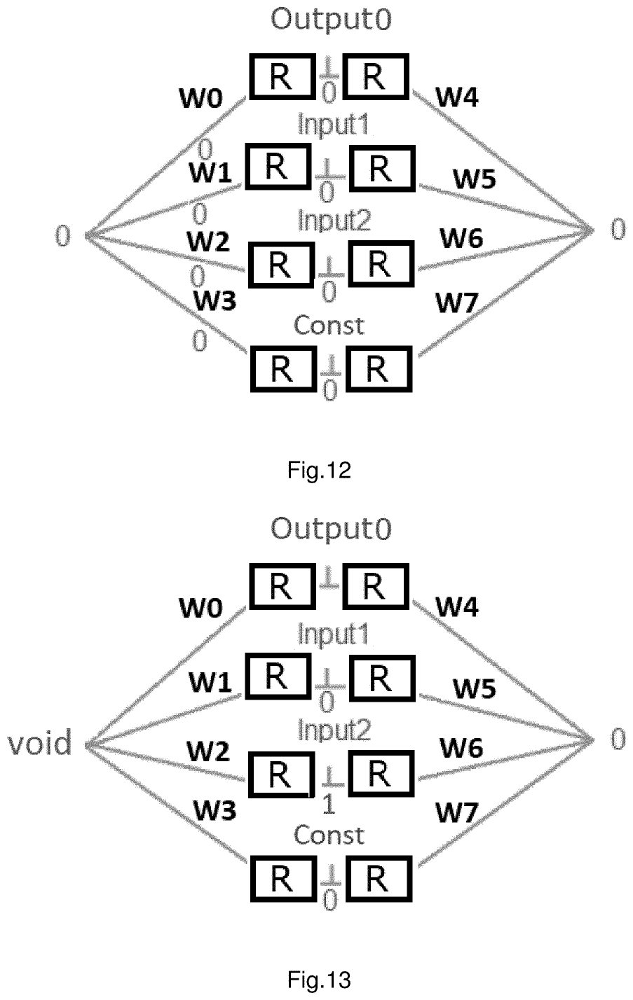

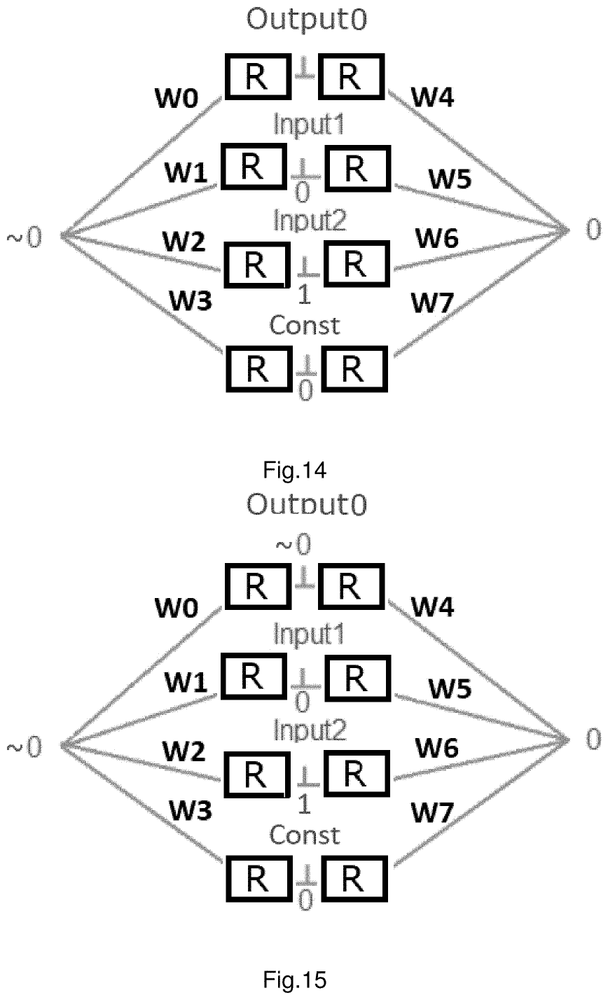

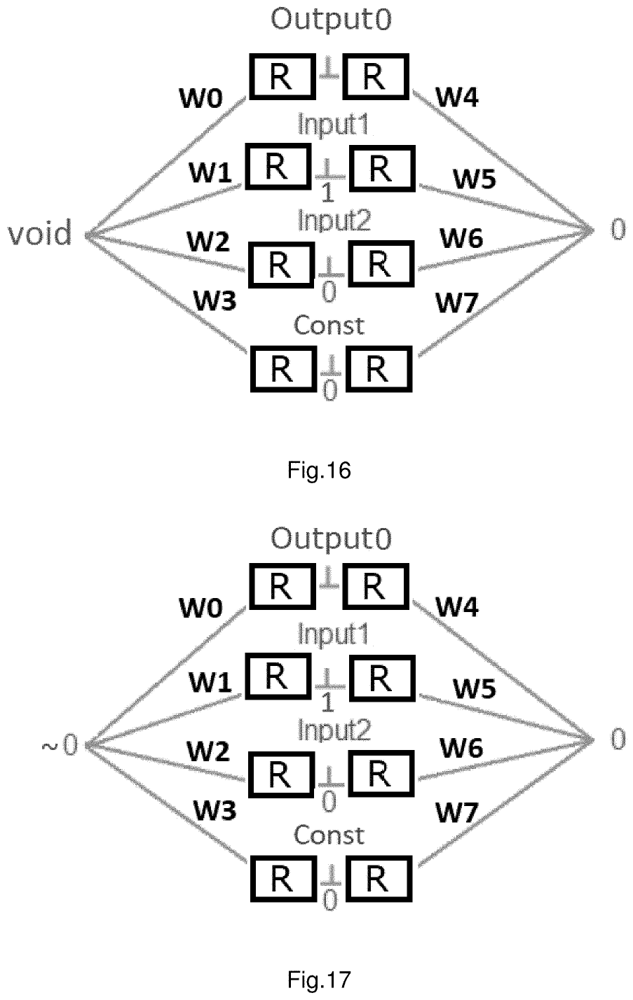

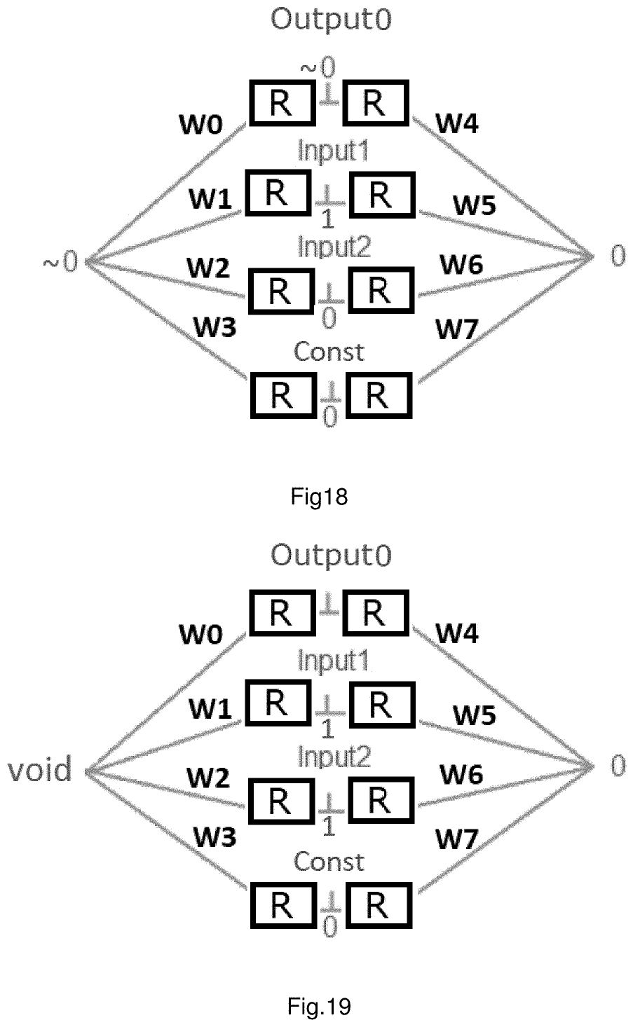

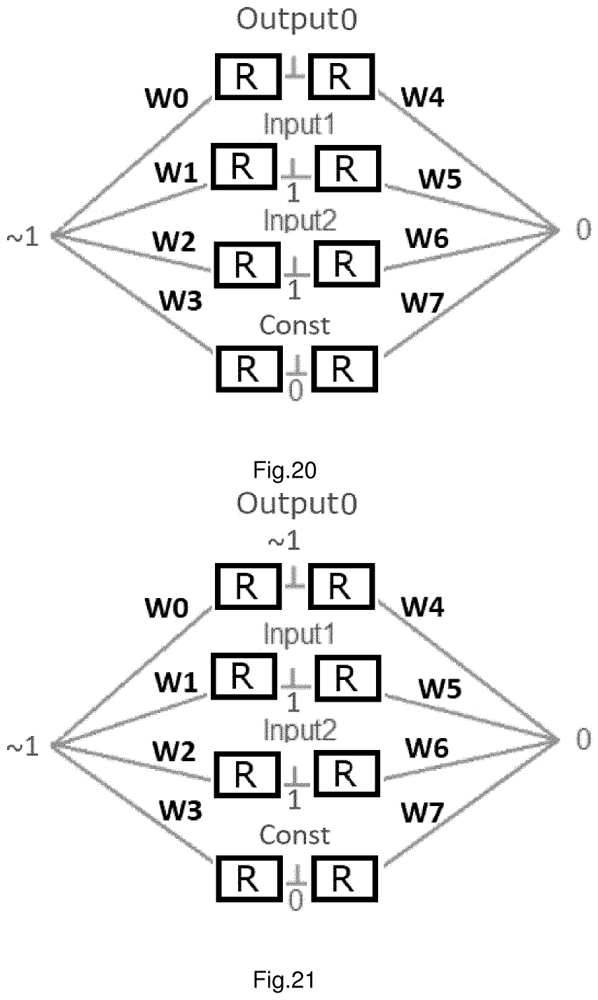

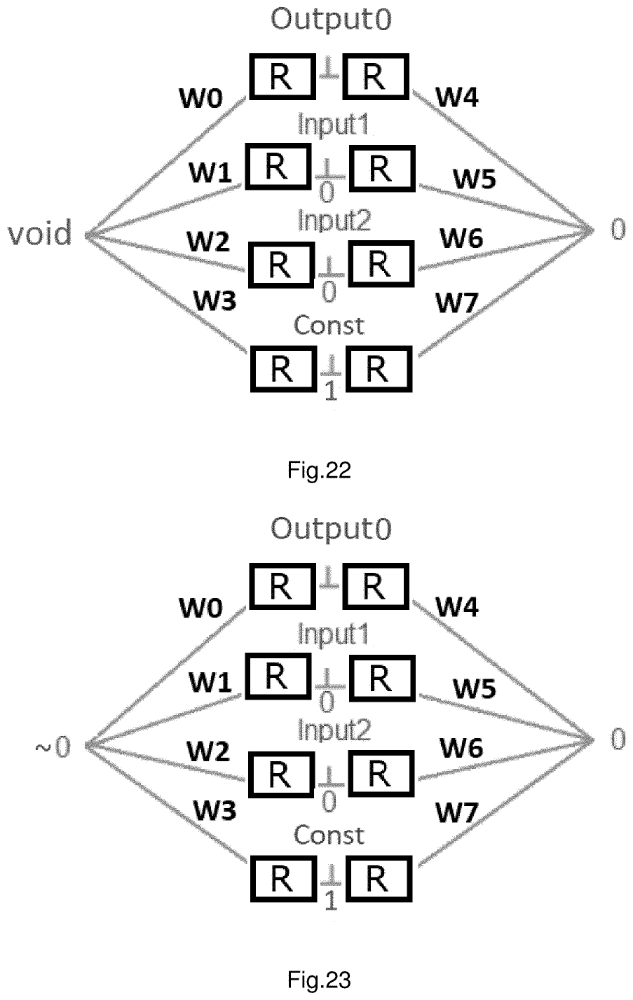

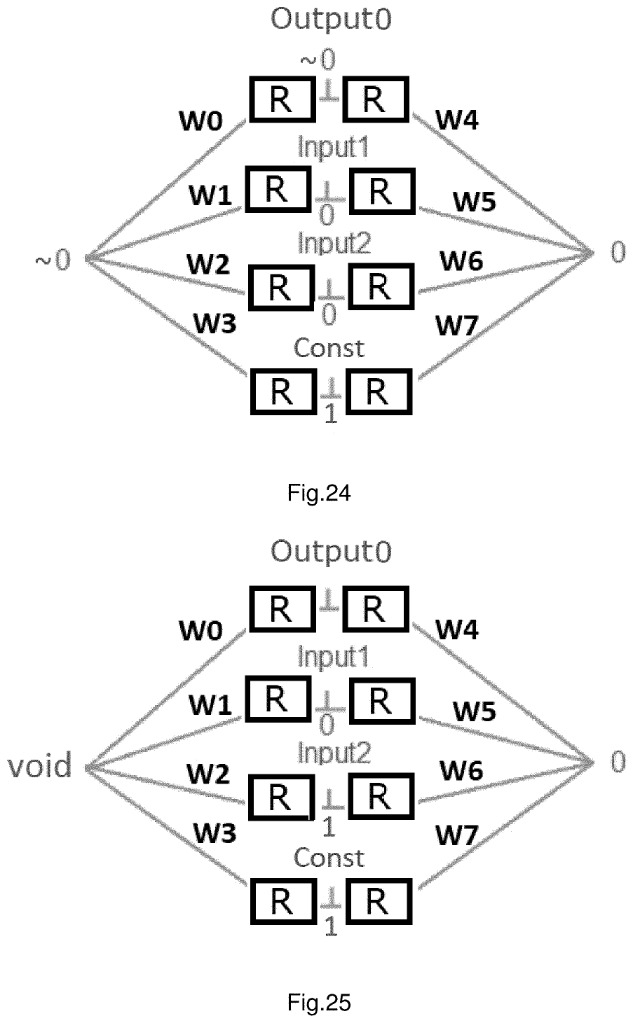

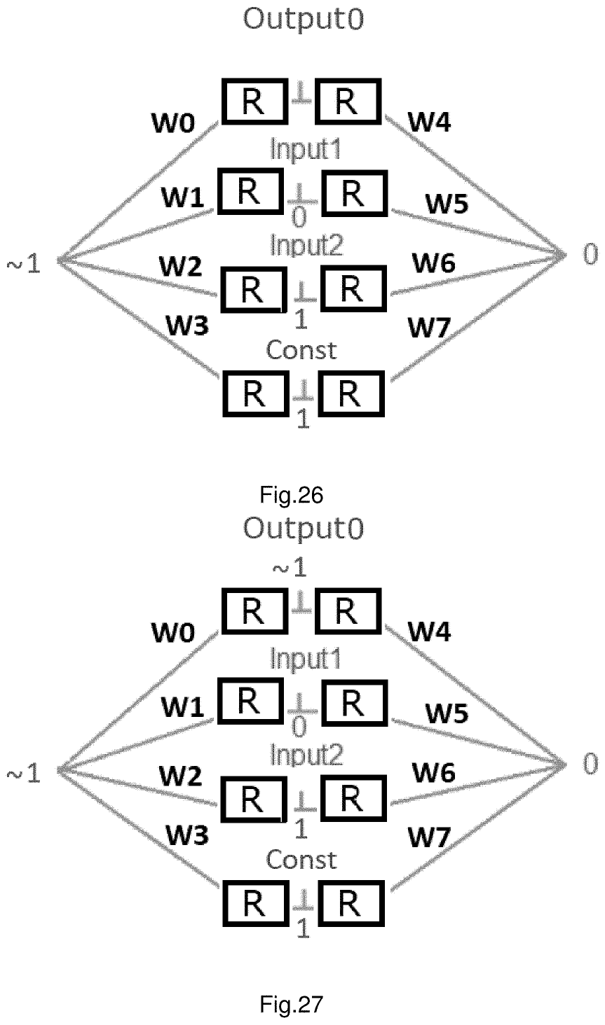

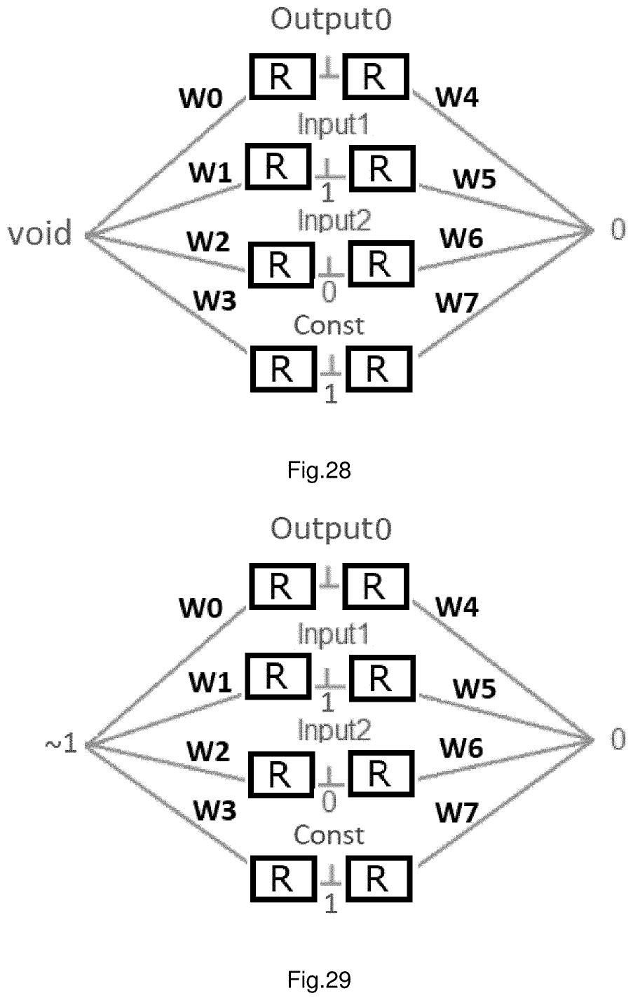

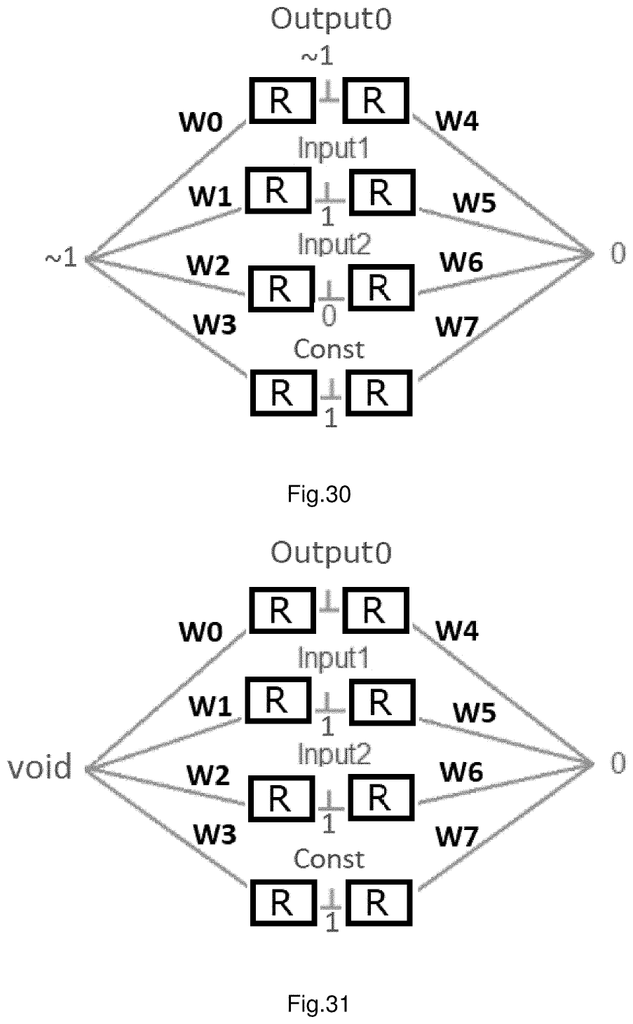

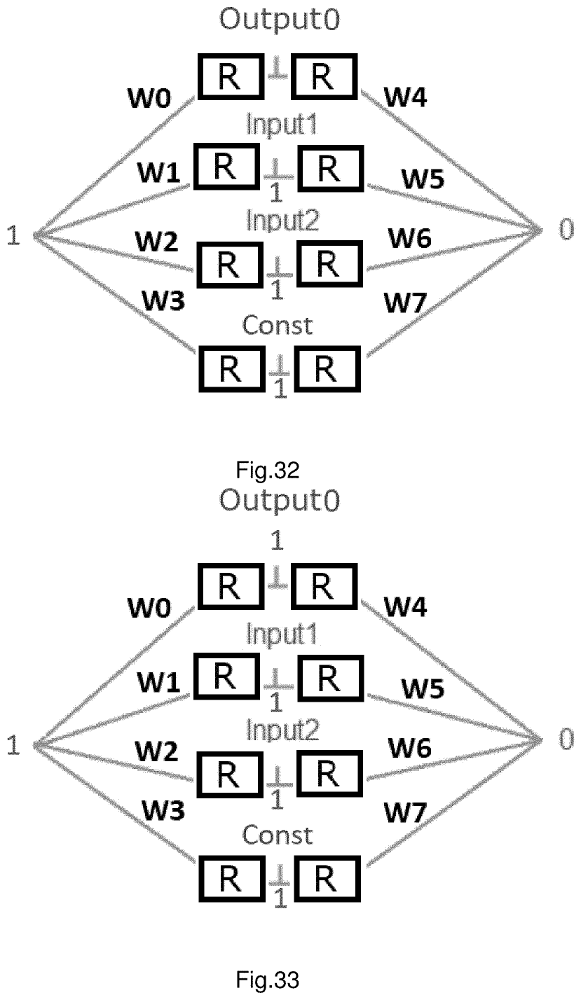

FIG. 10 to FIG. 33

Structure_of_an_electric_simple_function_majority_vote:

An electric version of the light behavior described above.

Showing a {majority_vote} simple_function of 3 simple_inputs {Input1, Input2, Const} and an approximation of their {Output0} result, using wires (resistances) only.

1 is encoded as power source (+).

0 is encoded as power source (−).

R is a resistance.

If we set the {Const} simple_input to 0, inputs {Input1, Input2} and output {Output0} would approximate a simple_function {“and” }.

If we set the {Const} simple_input to 1, inputs {Input1, Input2} and output {Output0} would approximate a simple_function {“or” }.

Initial configuration to have the output of the function:

{input1} is assigned a value.

{input2} is assigned a value.

{const} is assigned a value.

W4 is assigned a 0.

W5 is assigned a 0.

W6 is assigned a 0.

W7 is assigned a 0.

W0 is at void.

W1 is at void

W2 is at void

W3 is at void

So at initial configuration the encoding {W0, W1,W3,W2} or {const, input_1, input_2, out} of the simple_function {majority_vote} presented in FIG. 6 to FIG. 9 detailed structures text, and the encoding {W7, W5, W6, W4} of this simple_function are equal_codes.

Given this figure a simple_function {majority_vote} can be encoded as {const, input1, input2, output0}.

{const, input1,input2} is a reordrable_code.

Processes_of_double_function_majority_vote:

General Process

The process of a wire would start from an end and terminate on the other end. It terminates on the closer end of the next wire to start as described in the following text:

The wire w0 would start if output0 terminates.

The wire w1 would start if input1 terminates.

The wire w2 would start if input2 terminates.

The wire w3 would start if const terminates.

The wire output0 would start if w0 terminates.

The wire input1 would start if w1 terminates.

The wire input2 would start if w2 terminates.

The wire const would start if w3 terminates.

The wire w4 would start if output0 terminates.

The wire w5 would start if input1 terminates.

The wire w6 would start if input2 terminates.

The wire w7 would start if const terminates.

The wire output0 would start if w4 terminates.

The wire input1 would start if w5 terminates.

The wire input2 would start if w6 terminates.

The wire const would start if w4 terminates.

If one of the processes of the wires w0, w1, w2 or w3 terminates to their connection they would start from their connection.

If one of the processes of the wires w4, w5, w6 or w7 terminates to their connection they would start from their connection.
Case: {const} is put to simple_value 0 {majority_vote} behaves like an {“and” }.
Case: simple_values 00 give simple_value 0

Processes of the wires, input1, input2, const would start if values 0 0 0 are presented to {const, Input_1, Input_2} respectively.

The termination of w0 as a process would have {output0} have the simple_value 0. (in the range_of_encodings of 0).
Case: simple_values 10 give simple_value 0

Processes of the of the wires, input1, input2, const would start if values 0 1 0 are presented to {const, Input_1, Input_2} respectively.

The termination of w0 as a process would have {output0} have an approximation the simple_value 0. (in the range_of_encodings of 0).
Case: simple_values 01 give simple_value 0

Processes of the of the wires, input1, input2, const would start if values 0 0 1 are presented to {const, Input_1, Input_2} respectively.

The termination of w0 as a process would have {output0} have an approximation the simple_value 0. (in the range_of_encodings of 0).
Case: simple_values 11 give simple_value 1

Processes of the of the wires, input1, input2, const would start if values 0 1 1 are presented to {const, Input_1, Input_2} respectively.

The termination of w0 as a process would have {output0} have an approximation the simple_value 1. (in the range_of_encodings of 1).
Case: {const} is put to simple_value 1 {majority_vote} behaves like an {“or” }.
Case: simple_values 00 give simple_value 0

Processes of the of the wires, input1, input2, const would start if values 1 0 0 are presented to {const, Input_1, Input_2} respectively.

The termination of w0 as a process would have {output0} have an approximation the simple_value 0. (in the range_of_encodings of 0).
Case: simple_values 10 give simple_value 1

Processes of the of the wires, input1, input2, const would start if values 1 1 0 are presented to {const, Input_1, Input_2} respectively.

The termination of w0 as a process would have {output0} have an approximation the simple_value 1. (in the range_of_encodings of 1).
Case: simple_values 01 give simple_value 1

Processes of the of the wires, input1, input2, const would start if values 1 0 1 are presented to {const, Input_1, Input_2} respectively.

The termination of w0 as a process would have {output0} have an approximation the simple_value 1. (in the range_of_encodings of 1).
Case: simple_values 11 give simple_value 1

Processes of the of the wires, input1, input2, const would start if values 1 1 1 are presented to {const, Input_1, Input_2} respectively.

The termination of w0 as a process would have {output0} have the simple_value 1. (in the range_of_encodings of 1).

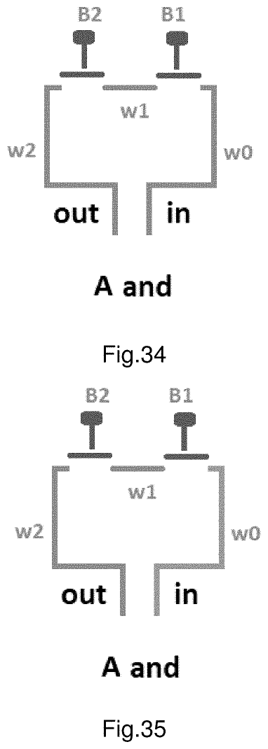

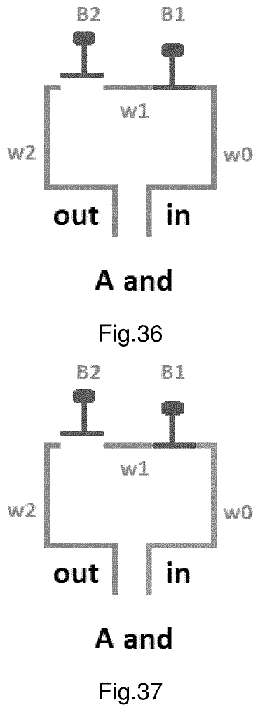

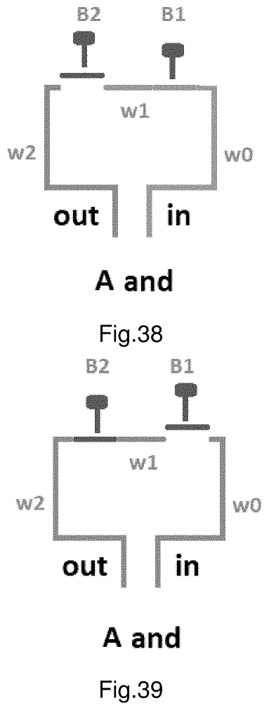

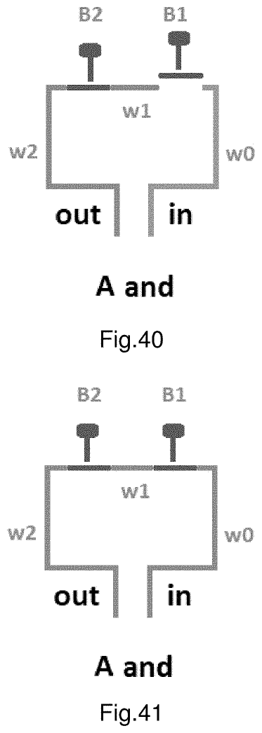

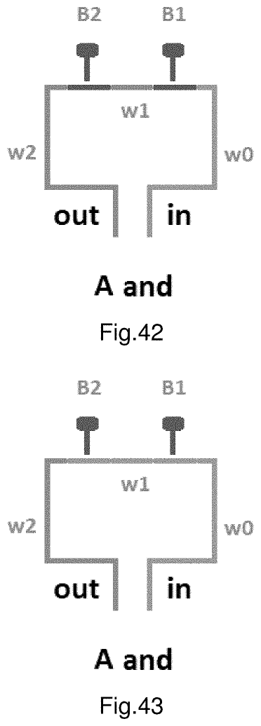

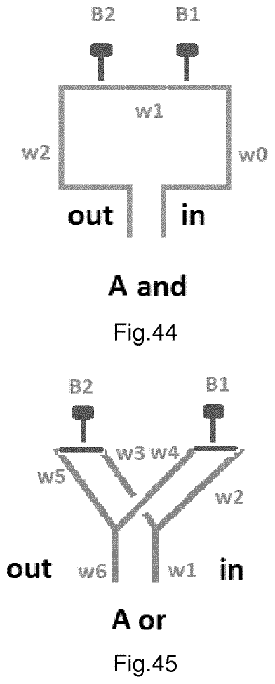

FIG. 34 to FIG. 44:

Structure_of_simple_function_and:

A simple_function {“and” }.

{b1} is a Super_button of type Y it is a super_input encoded here as in1.

{b2} is a Super_button of type Y it is a super_input encoded here as in2.

{in1,in2} is a reordrable_code.

A wire gets from {in} through two buttons to {out}.

{In} is put to a value.

{out} would have a Super_value expressing the “and” of the two buttons.

{in,out} form a super_wire that is a super_output encoded here as out0.

The Super_value of {out} is the one of the super_output {out0}.

Given this figure a simple_function {“and” } can be encoded as {in1,in2,out0}.

Processes_of_double_function_and:

General Process

The wire w2 as a process would start if the Super_button {b2} as a process terminates.

The Super_button {b2} as a process would start if the wire w1 as a process terminates.

The wire w1 as a process would start if the Super_button {b1} as a process terminates.

The Super_button {b1} as a process would start if the wire w0 as a process terminates.
Case: super_values 00 give super_value 0

The wire w0 as a process would start if a Super_1 meaning a value is presented at {in}.

A super_0 would be at {out} due to no execution of the processes B1, w1, B2, w2 and it would be the final value of {out0}.
Case: super_values 01 give super_value 0

The wire w0 as a process would start if a Super_1 meaning a value is presented at {in}.

A super_0 would be at {out} due to no execution of the processes B2, w2 and it would be the final value of {out0}.
Case: super_values 10 give super_value 0

The wire w0 as a process would start if a Super_1 meaning a value is presented at {in}.

A super_0 would be at {out} due to no execution of the processes B1, w1, B2, w2 and it would be the final value of {out0}.
Case: super_values 11 give super_value 1

The wire w0 as a process would start if a Super_1 meaning a value is presented at {in}.

A super_0 would be at {out} due to the execution of the processes B1, w1, B2, w2 and it would be the final value of {out0}.

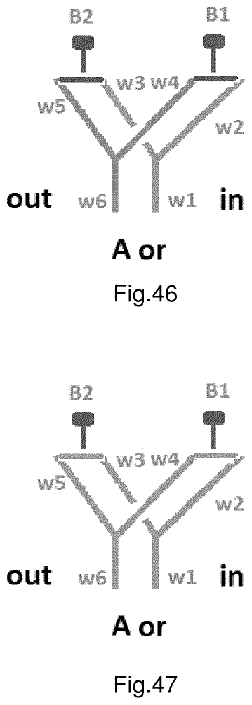

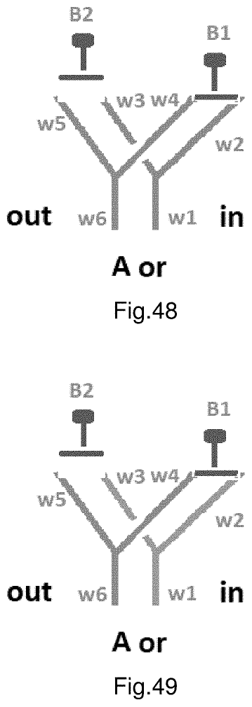

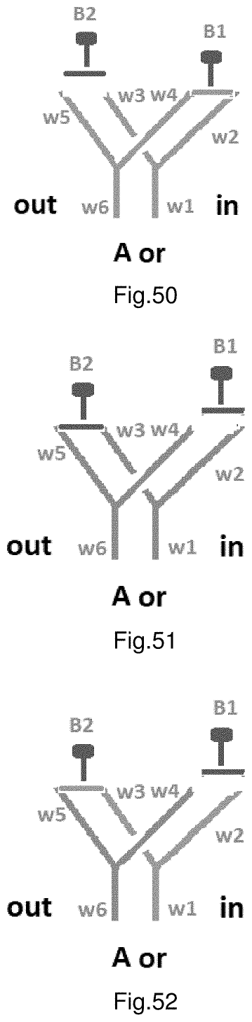

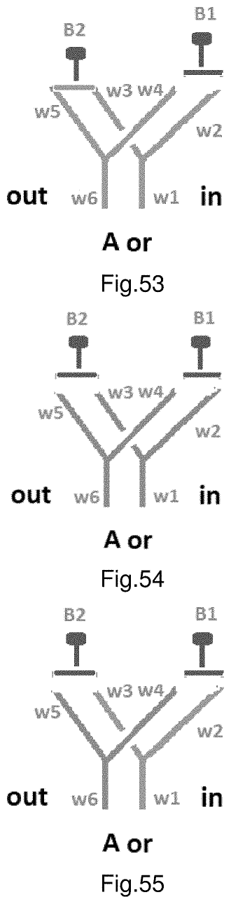

FIG. 45 to FIG. 55:

Structure_of_simple_function_or:

A simple_function {“or” }.

{b1} is a Super_button of type Y it is a super_input encoded here as in1.

{b2} is a Super_button of type Y it is a super_input encoded here as in2.

{in1,in2} is a reordrable_code.

A wire gets from {in} splitting to two wires through two buttons and reunite to {out}.

{In} is put to a super_1.

{out} would have a Super_value expressing the “or” of the two buttons.

{in,out} form a super_wire that is a super_output encoded here as out0.

The Super_value of {out} is the one of the super_output {out0}.

Given this figure a simple_function {“or” } can be encoded as {in1,in2,out0}.

Processes_of_simple_function_or:

General Process

The wire w6 as a process would start if the one of the wires w5,w4 as processes would terminate.

The wire w5 as a process would start if the Super_button {b2} as a process terminates.

The wire w4 as a process would start if the Super_button {b1} as a process terminates.

The Super_button {b2} as a process would start if the wire w3 as a process terminates.

The Super_button {b1} as a process would start if the wire w2 as a process terminates.

The wires w2,w3 as processes would start if the wire w1 as a process terminates.

The wire w1 as a process would start if a Super_1 meaning a value is presented at {in}.
Case: super_values 00 give super_value 0

A super_0 would be at {out} and it would be the final value of {out0}.
Case: super_values 01 give super_value 1

A super_1 would be at {out} and it would be the final value of {out0}.
Case: super_values 10 give super_value 1

A super_1 would be at {out} and it would be the final value of {out0}.
Case: super_values 11 give super_value 1

A super_1 would be at {out} and it would be the final value of {out0}.

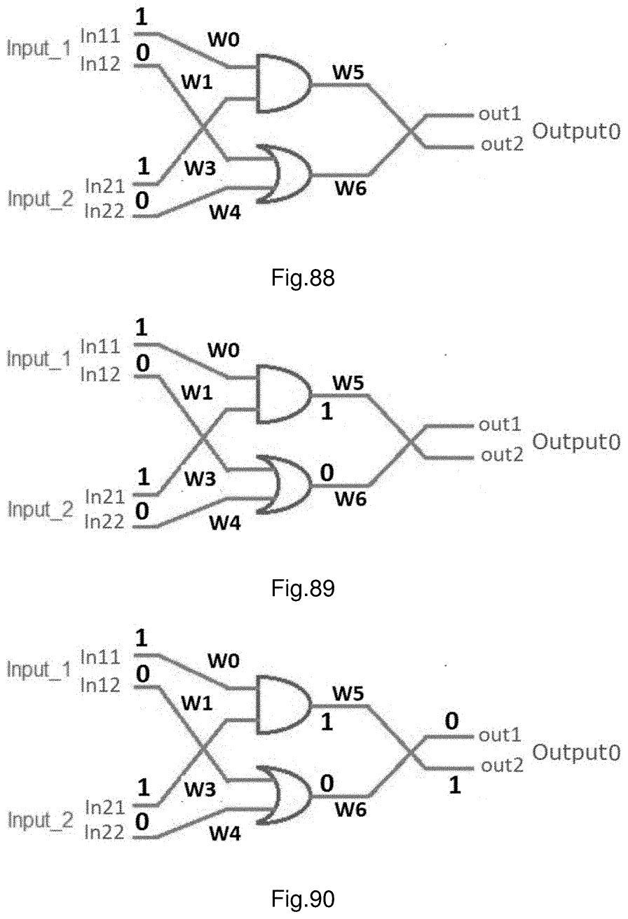

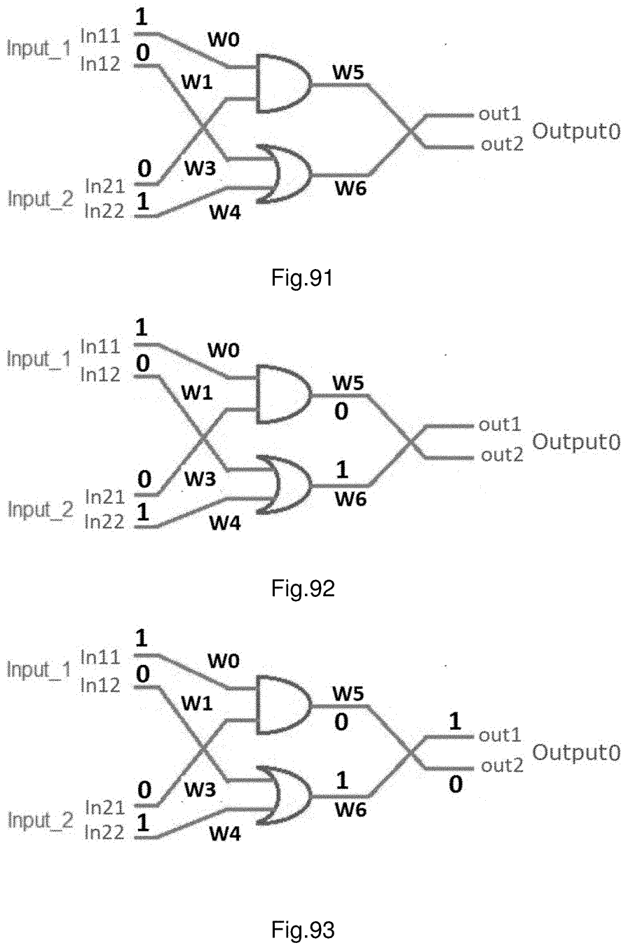

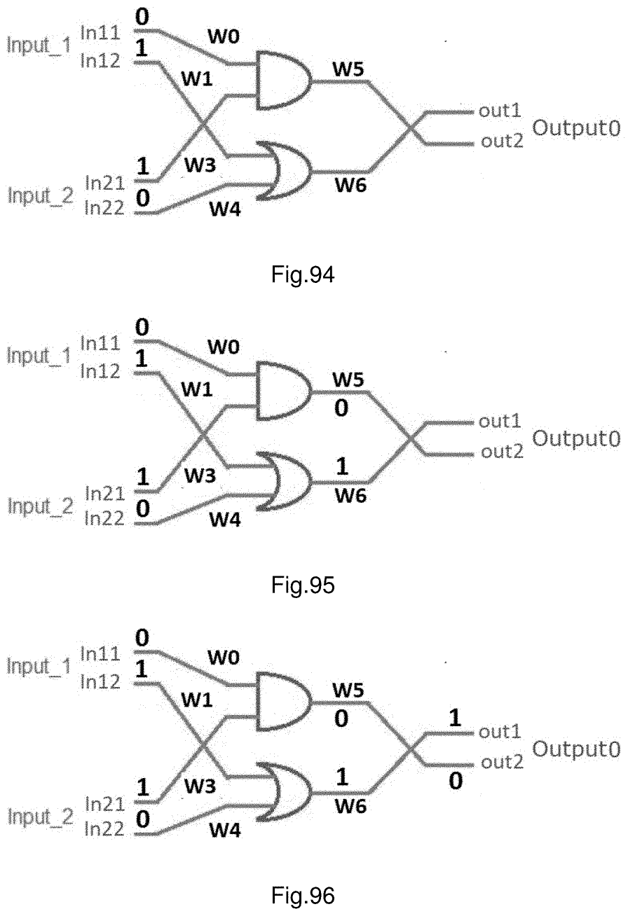

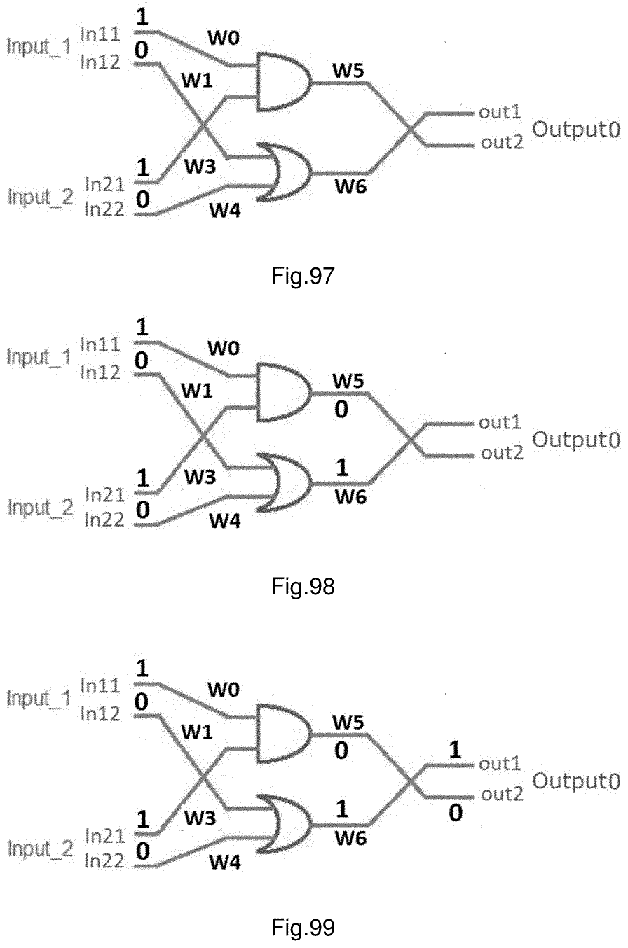

FIG. 88 to FIG. 99:

Structure_of_double_function_nor:

If:

1 is encoding 0,

0

and

0 is encoding 1.

1

Showing how to make a universal double_function {nor} using the simple_functions {“and”,“or” } with the help of the double_function {not(x)} described in FIG. 5.

A double_function {nor} can be composed of:
double_input {Input_1} made with two simple_inputs encoded from top to bottom as In_11 and In_12.
double_input {Input_2} made with two simple_inputs encoded from top to bottom as In_21 and In_22.
double_output {Output0} made with two simple_inputs encoded from top to bottom as out_1 and out_2.
simple_function {“and” } have inputs {In_11, In_21} and output {out2}, it is encoded as ({In_11, In_21, out2}.
simple_function {“or” } have inputs {In_12, In_22} and output {out1}, it is encoded as {In_12, In_22, out1}.
wires {W5, W6} are an encoding of double_function {not(x)} presented in FIG. 5.
{input_1,input_2} is a reordrable_code.

Wire W1 is different from wire W3 (no connection).

Wire W5 is different from wire W6 (no connection).

This figure is demonstrating a universal group of functions that creates a {nor}.

Given this figure a simple_function {nor} can be encoded as {W0,W3,W6} it can also be encoded as {in11, in21, out1} the 2 are equal_codes.

Given this figure a double_function {nor} can be encoded as {in11,in12,in21,in22,out1,out2}, it can also be encoded as {W0, W1, W3, W4, W6, W5} the two are equal_codes.

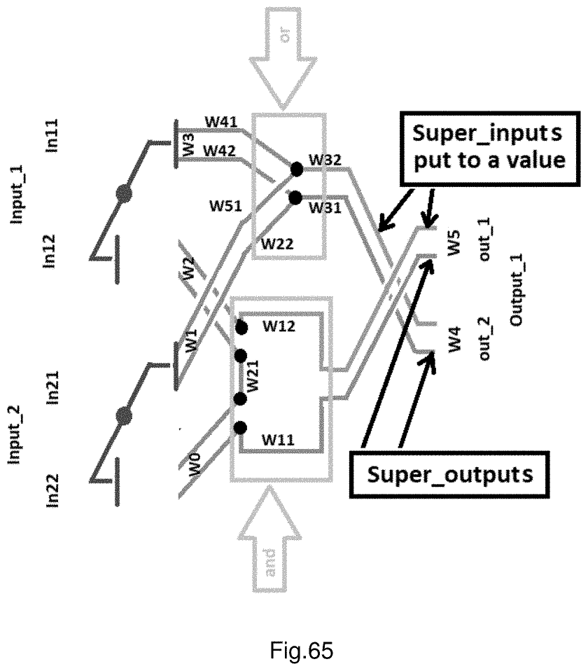

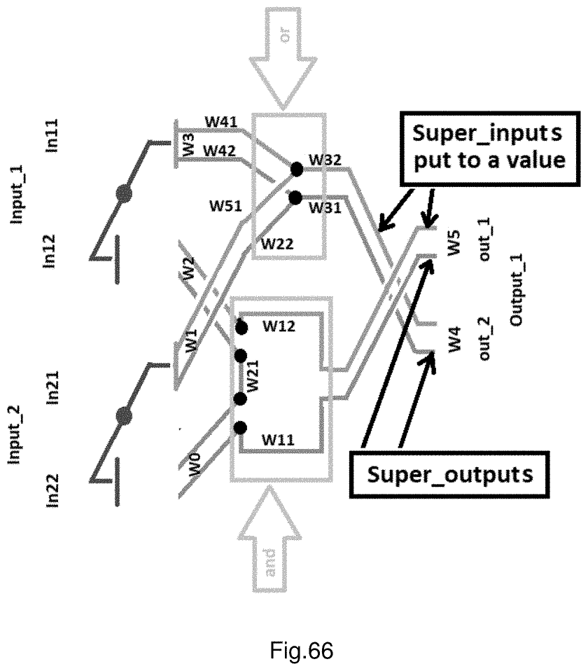

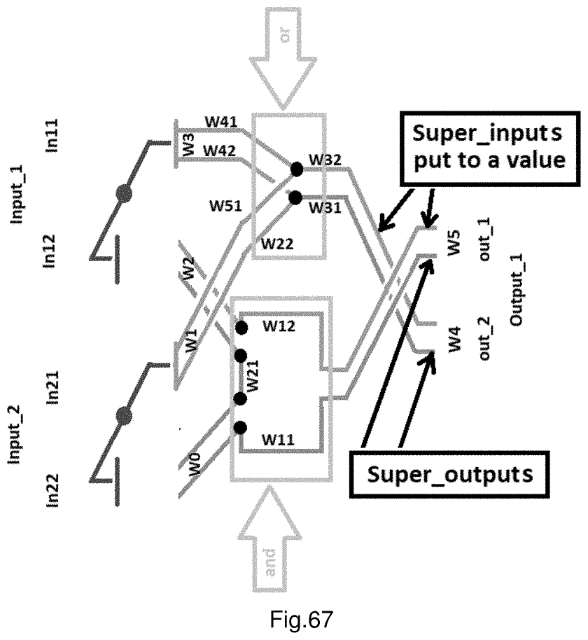

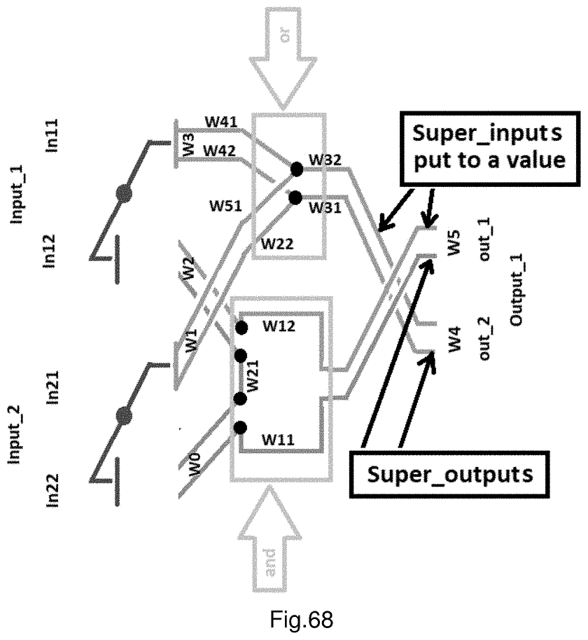

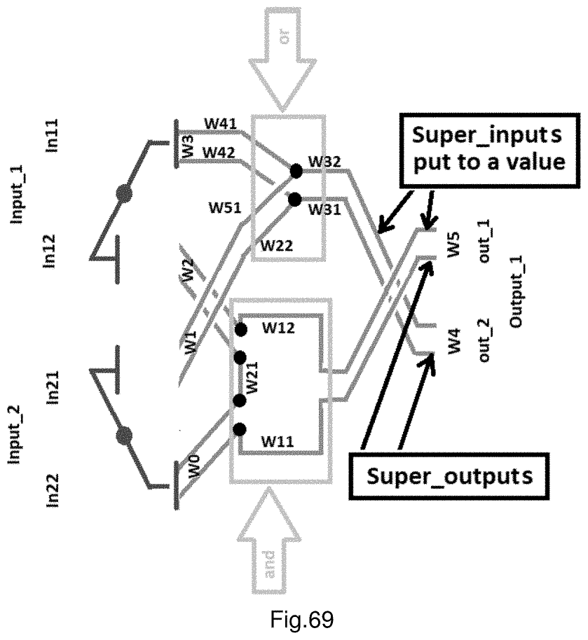

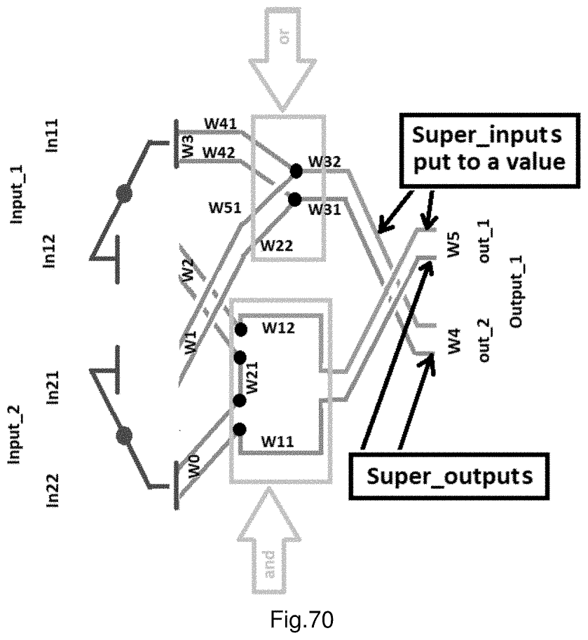

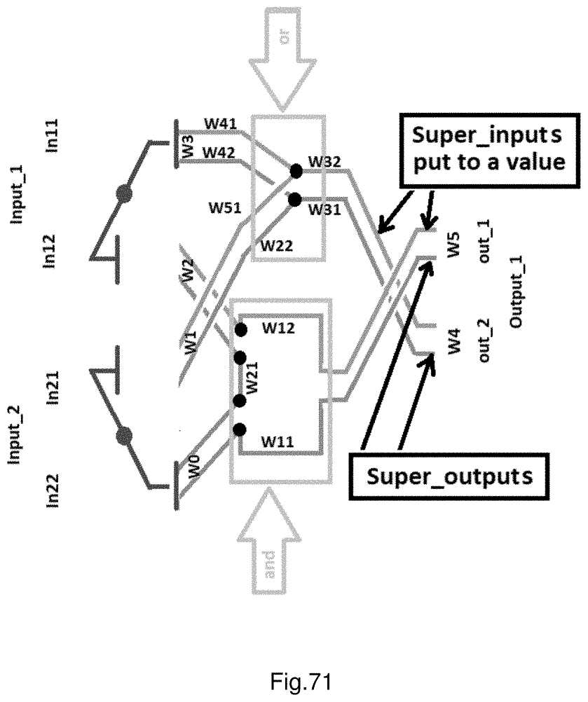

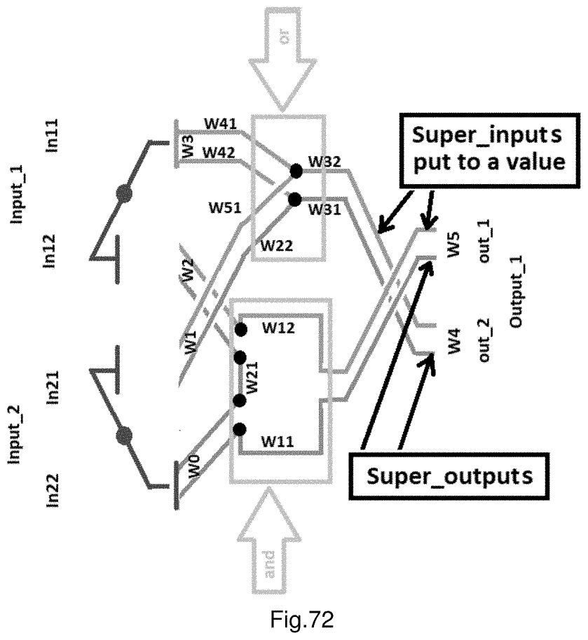

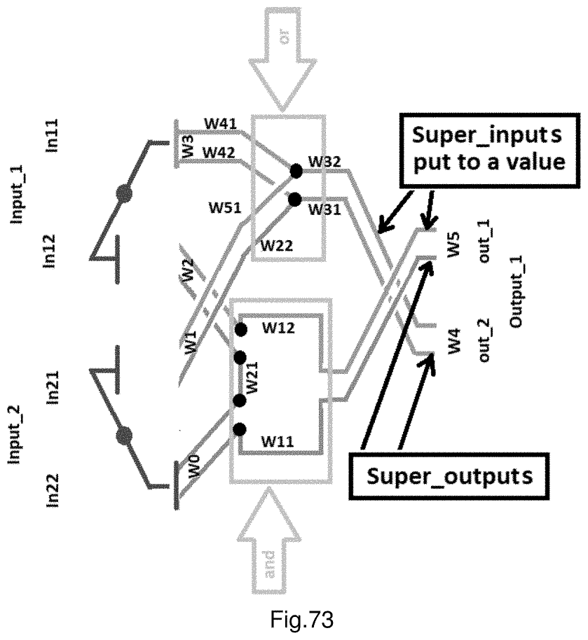

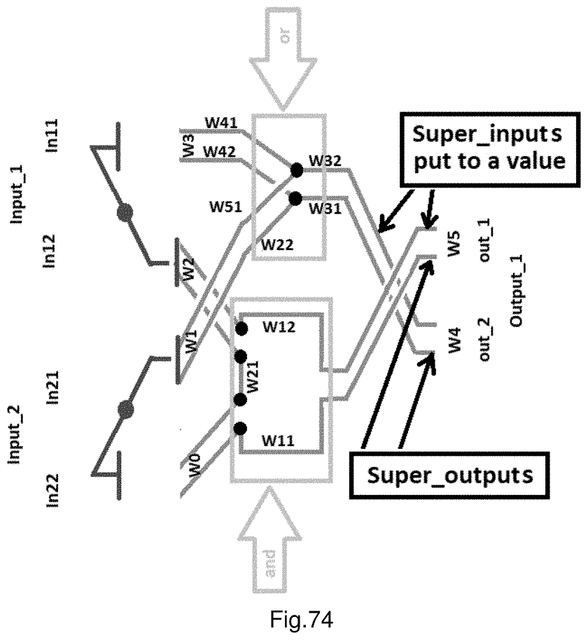

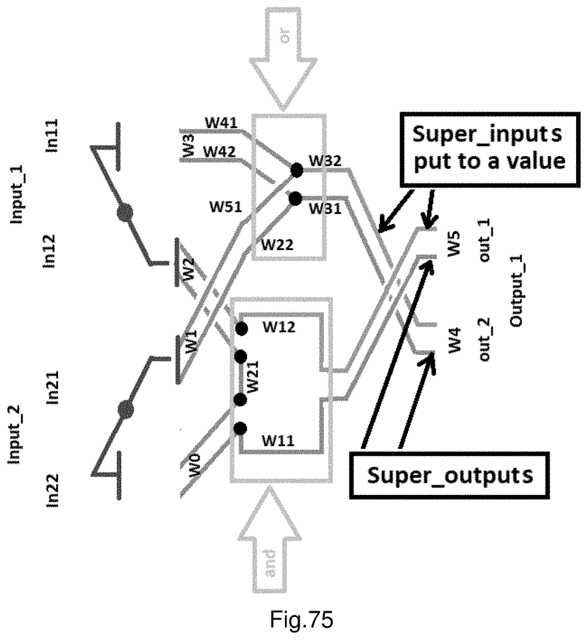

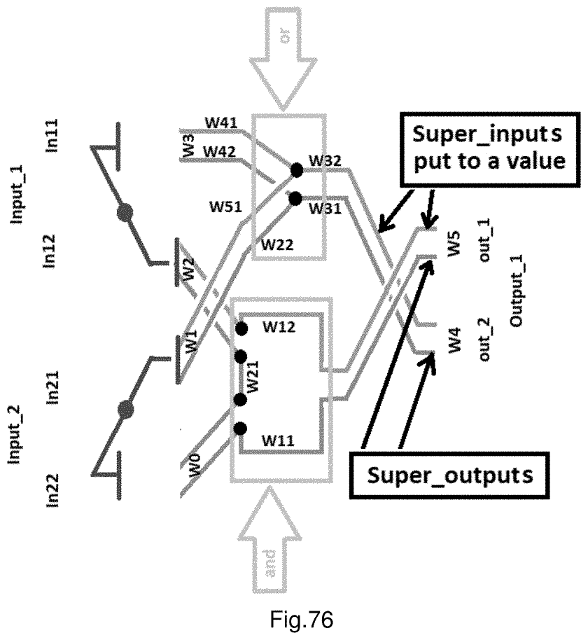

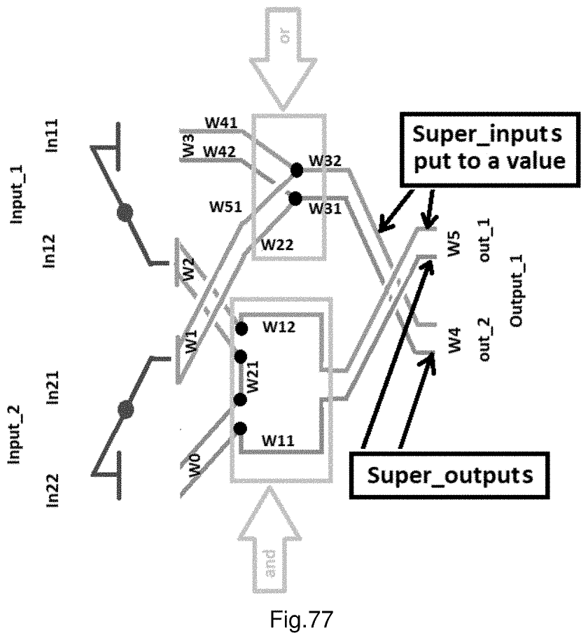

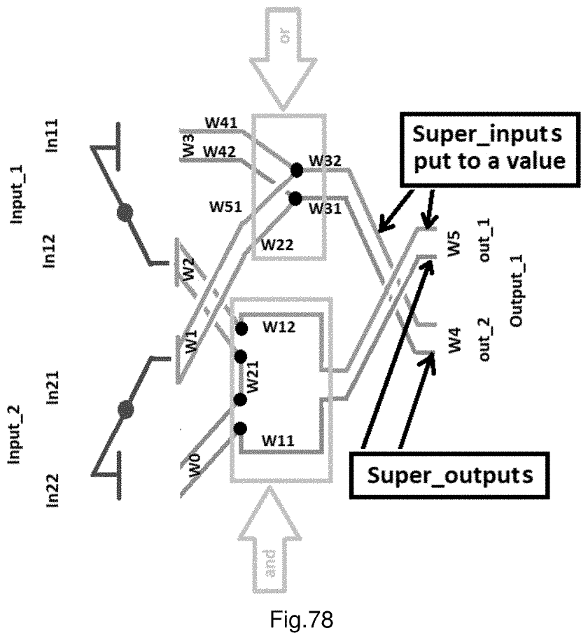

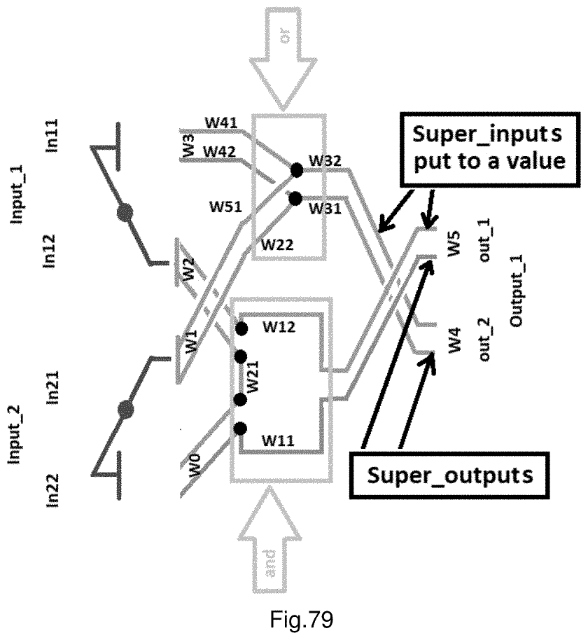

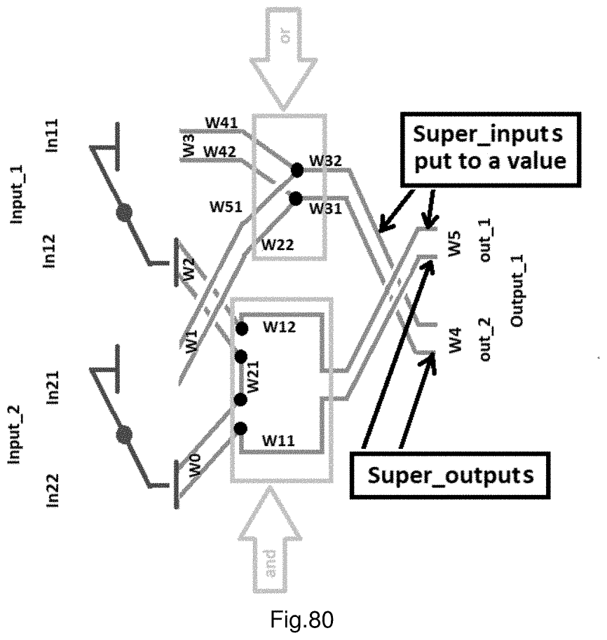

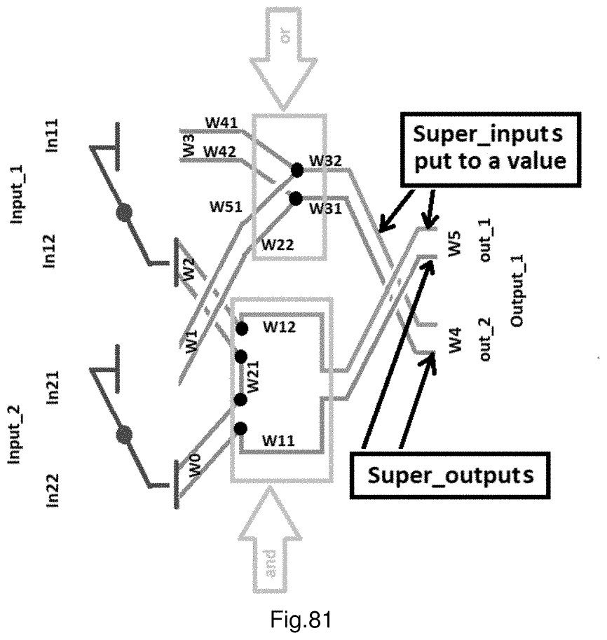

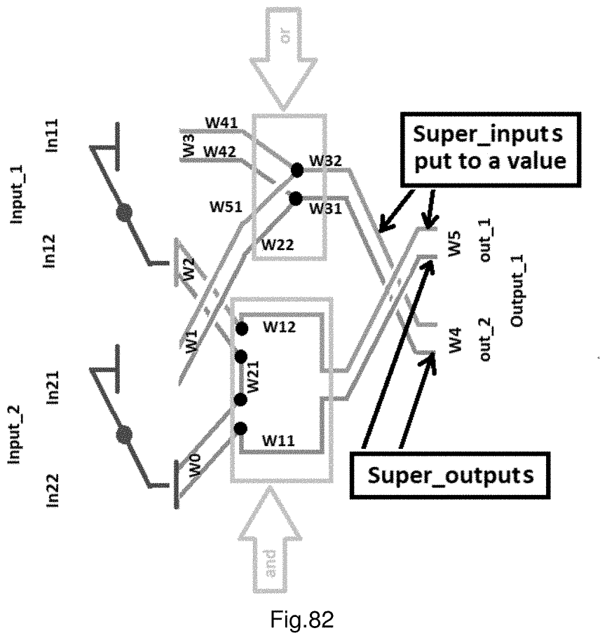

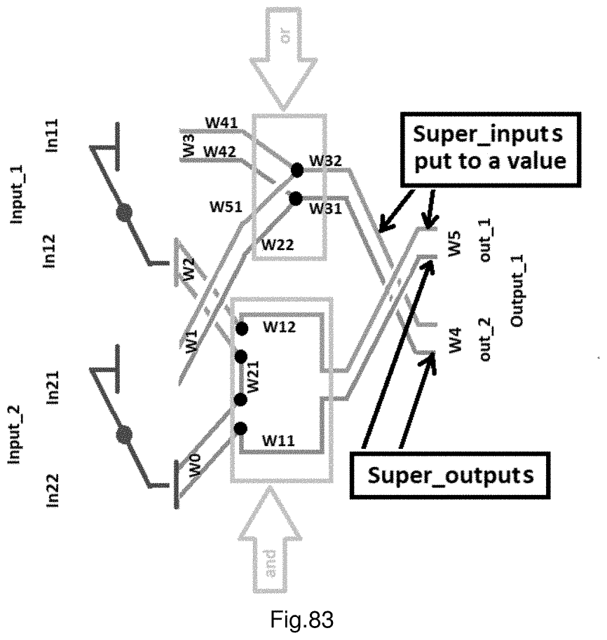

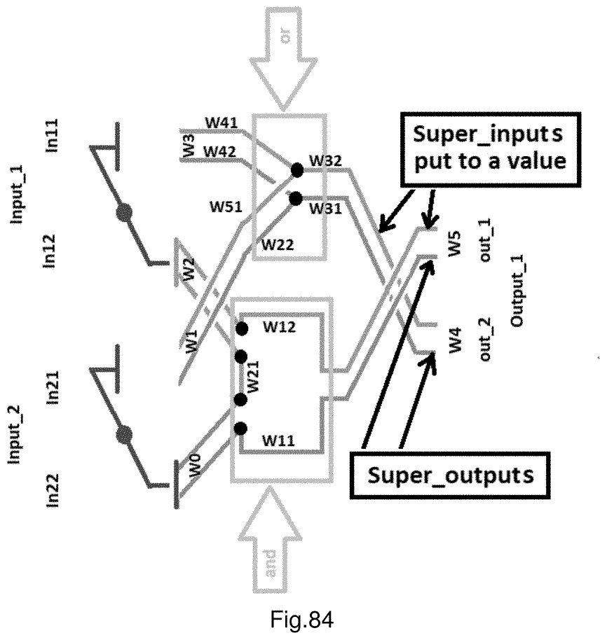

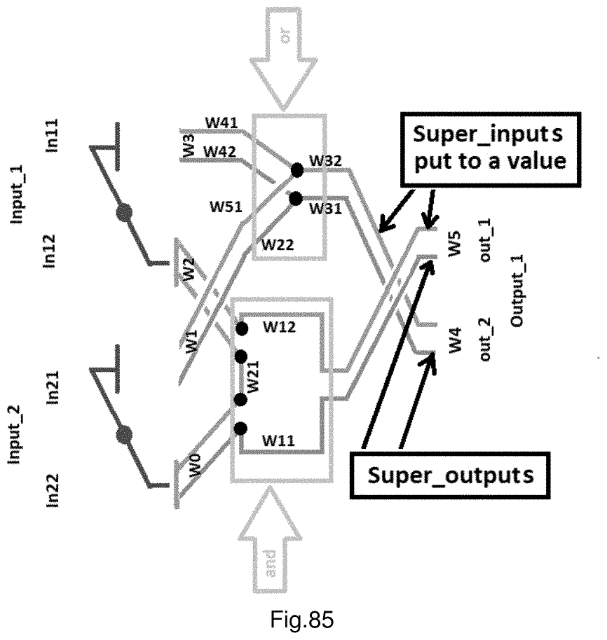

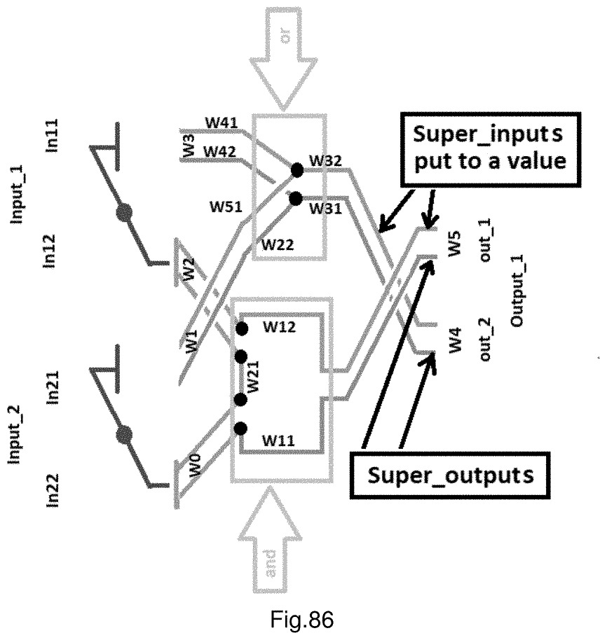

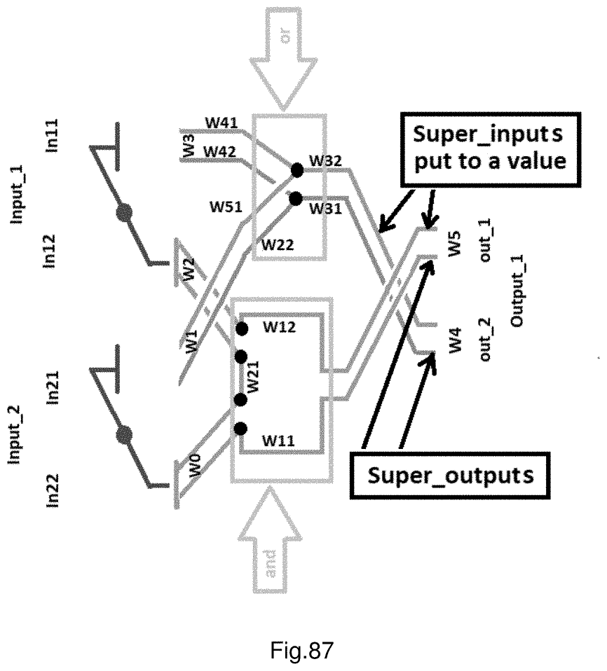

FIG. 64 to FIG. 87 show how to use the {“and” } and the {“or” } described in FIG. 34 to FIG. 55 to achieve the structure of a double function nor.

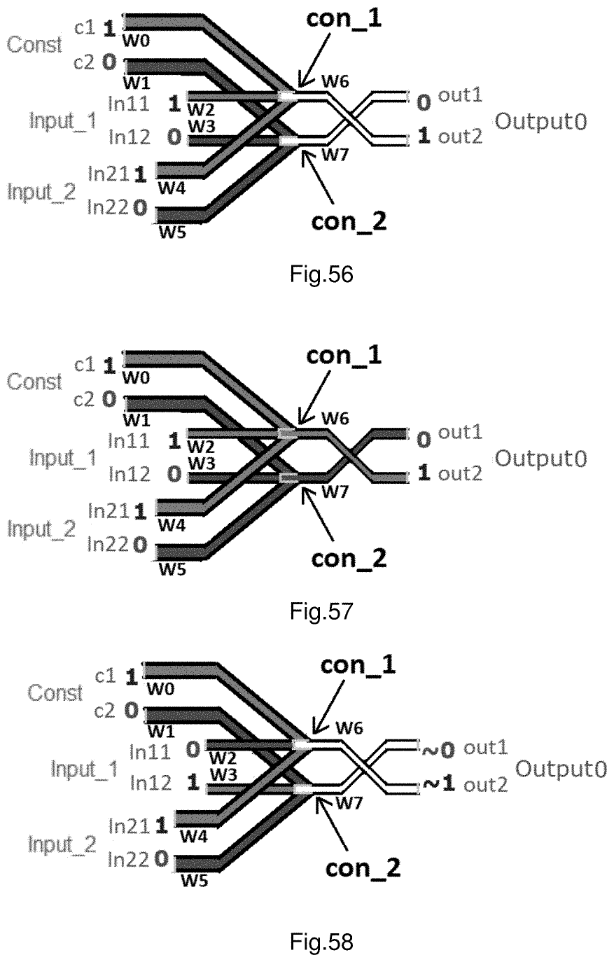

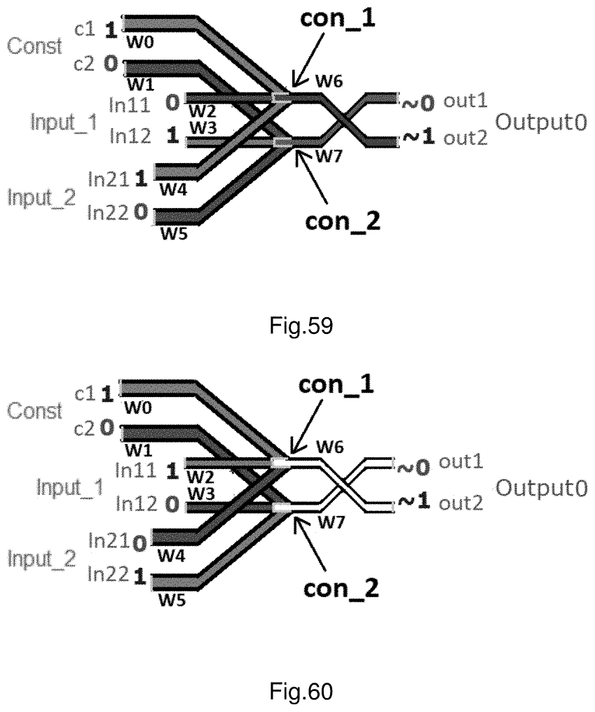

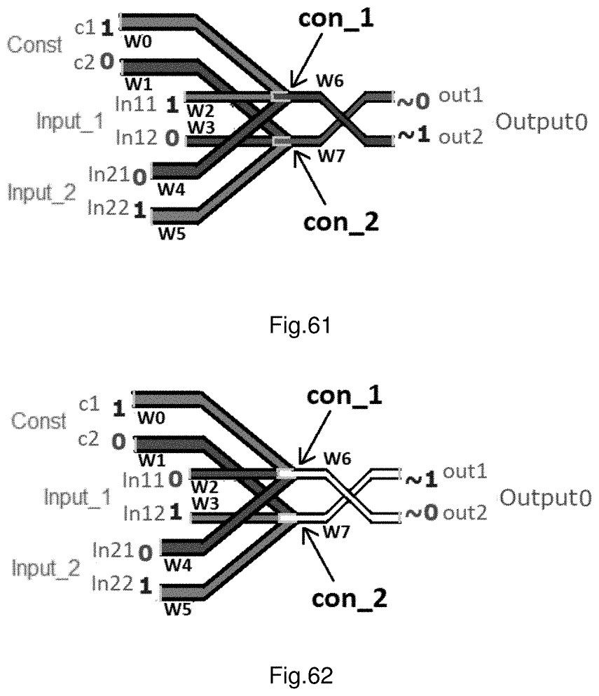

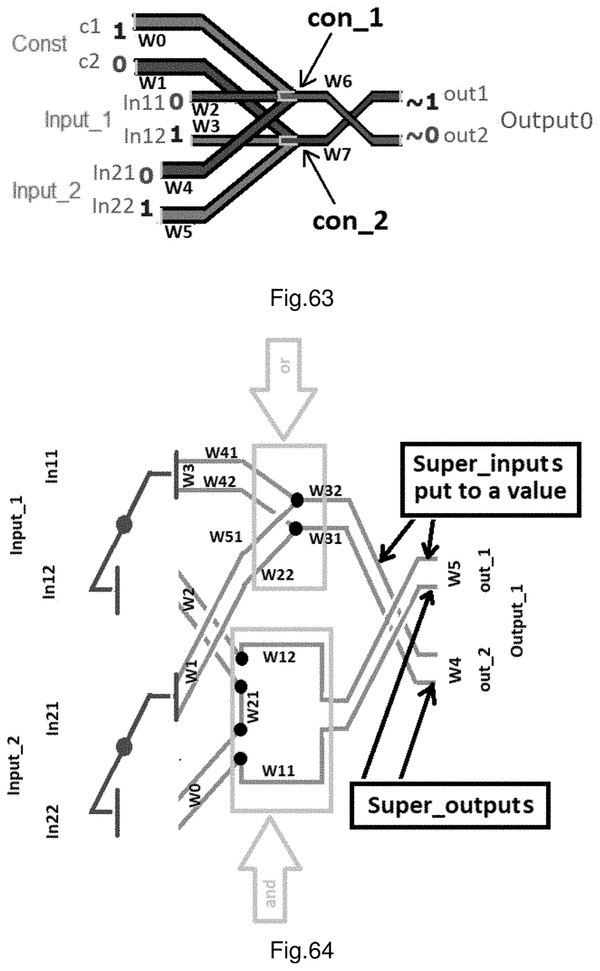

FIG. 56 to FIG. 63 show how to use the {“and” } and the {“or” } described in FIG. 6 to FIG. 9 to achieve the structure of a double function nor.

Using the {“and” } and the {“or” } described in FIG. 10 to FIG. 33 is also possible.

To notice that:

The encoding {0, input_1, input_2, out} of the simple_function {majority_vote} presented in FIG. 6 to FIG. 9, the encoding {0, W5, W6, W4} of the simple_function {majority_vote} presented in FIG. 10 to FIG. 33, the encoding {in1,in2,out0} of the simple_function {“and” } presented in FIG. 34 to FIG. 44, the encoding {w2,w0,w5} of the simple_function {“and” } presented in FIG. 64 to FIG. 87 and the encoding {w0,w3,w5} of the simple_function {“and” } presented in FIG. 88 to FIG. 99 are super_equal_codes.

The encoding {1, input_1, input_2, out} of the simple_function {majority_vote} presented in FIG. 6 to FIG. 9, the encoding {1, W5, W6, W4} of the simple_function {majority_vote} presented in FIG. 10 to FIG. 33, the encoding {in1,in2,out0} of the simple_function {“or” } presented in FIG. 45 to FIG. 55, the encoding {w3,w1,w4} of the simple_function {“or” } presented in FIG. 64 to FIG. 87 and the encoding {w1,w4,w6} of the simple_function {“or” } presented in FIG. 88 to FIG. 99 are super_equal_codes.

Processes_of_double_function_nor:

General Process

The wire w5 as a process would start if the function {“and” } as a process terminates.

The wire w6 as a process would start if the function {“or” } as a process terminates.

The function {“and” } as a process would start if the wires w0 and w1 as processes would terminate.

The function {“or” } as a process would start if the wires w3 and w4 as processes would terminate.
Case: double_values 00 give double_value 1

Processes of the wires w0,w1, w3 and w4 would start if values 1 0 1 0 are presented to {In11, In12, In21, In22} respectively.

The termination of w5, w6 as processes would have {output0} have the double_value 1.
Case: double_values 01 give double_value 0

Processes of the wires w0,w1, w3 and w4 would start if values 1 0 0 1 are presented to {In11, In12, In21, In22} respectively.

The termination of w5, w6 as processes would have {output0} have the double_value 0.
Case: double_values 10 give double_value 0

Processes of the wires w0,w1, w3 and w4 would start if values 0 1 1 0 are presented to {In11, In12, In21, In22} respectively.

The termination of w5, w6 as processes would have {output0} have the double_value 0.
Case: double_values 11 give double_value 0

Processes of the wires w0,w1, w3 and w4 would start if values 0 1 0 1 are presented to {In11, In12, In21, In22} respectively.

The termination of w5, w6 as processes would have {output0} have the double_value 0.

If:

1 is encoding 1,

0

and

0 is encoding 0.

1

Structure_of_double_function_nor:

would become

Structure_of_double_function_nand:

without changing anything else.

Processes_of_double_function_nand:

General Process

The wire w5 as a process would start if the function {“and” } as a process terminates.

The wire w6 as a process would start if the function {“or” } as a process terminates.

The function {“and” } as a process would start if the wires w0 and w1 as processes would terminate.

The function {“or” } as a process would start if the wires w3 and w4 as processes would terminate.
Case: double_values 00 give double_value 1

Processes of the wires w0,w1, w3 and w4 would start if values 0 1 0 1 are presented to {In11, In12, In21, In22} respectively.

The termination of w5, w6 as processes would have {output0} have the double_value 1.
Case: double_values 01 give double_value 1

Processes of the wires w0,w1, w3 and w4 would start if values 0 1 1 0 are presented to {In11, In12, In21, In22} respectively.

The termination of w5, w6 as processes would have {output0} have the double_value 1.
Case: double_values 10 give double_value 1

Processes of the wires w0,w1, w3 and w4 would start if values 1 0 0 1 are presented to {In11, In12, In21, In22} respectively.

The termination of w5, w6 as processes would have {output0} have the double_value 1.
Case: double_values 11 give double_value 0

Processes of the wires w0,w1, w3 and w4 would start if values 1 0 1 0 are presented to {In11, In12, In21, In22} respectively.

The termination of w5, w6 as processes would have {output0} have the double_value 0.

What I claim is:

1) The process encoded as not(x) with a structure described in the section Structure_of_double_function_not_x and with steps described in the section Processes_of_double_function_not_x.

2) The process encoded as nor with a structure described in the section structure_of_double_function_nor and with steps described in the section processes_of_double_function_nor.

3) The process encoded as nand with a structure described in the section structure_of_double_function_nand and with steps described in the section processes_of_double_function_nand.
